(19) United States
(12) Patent Application Publication
(10) Pub. No.: US 2025/0107137 A1
(43) Pub. Date: Mar. 27, 2025

(54) LATERAL POWER SEMICONDUCTOR DEVICE LAYOUT AND DEVICE STRUCTURE

(71) Applicant: University of Electronic Science and Technology of China, Chengdu (CN)

(72) Inventors: Ming QIAO, Chengdu (CN); Jiawei WANG, Chengdu (CN); Dingxiang MA, Chengdu (CN); Yue GAO, Chengdu (CN); Gen LIU, Chengdu (CN); Shengduo WANG, Chengdu (CN); Yuanqing YE, Chengdu (CN); Bo ZHANG, Chengdu (CN)

(73) Assignee: University of Electronic Science and Technology of China, Chengdu (CN)

(21) Appl. No.: 18/398,222

(22) Filed: Dec. 28, 2023

(30) Foreign Application Priority Data
Sep. 25, 2023 (CN) 202311250466.2

(51) Int. Cl. H01L 29/78; H01L 29/06; H01L 29/417

(52) U.S. Cl. CPC H10D 30/65; H10D 62/127; H10D 64/257

(57) ABSTRACT

A lateral power semiconductor device layout and a device structure belong to the technical field of power semiconductor devices. A method for designing a lateral power semiconductor device layout with high integrity and high cell density has the following advantages of reducing a specific on-resistance of the device, increasing a width of a channel per unit area, improving the current capability of the device, optimizing the static characteristic of the device, reducing the area of a drain region and the parasitic capacitance of the device, reducing the delay time of a cell switch caused by an excessively long gate electrode of a traditional finger cell, optimizing the dynamic characteristic of the device, optimizing the cell edge of the device and the curvature effect of a terminal, and reducing the pre-breakdown risk of the device.

### CROSS REFERENCE TO THE RELATED APPLICATIONS

This application is based upon and claims foreign priority to Chinese Patent Application No. 202311250466.2, filed on Sep. 25, 2023, the entire content of which is incorporated herein by reference.

### TECHNICAL FIELD

The present invention belongs to the technical field of power semiconductors, and relates to a lateral power semiconductor device layout and a device structure.

### BACKGROUND

A laterally double-diffused metal oxide semiconductor (LDMOS) device is convenient to integrate, thereby being widely applied to a smart power integrated circuit (SPIC).

In traditional SPIC layout design, LDMOS is often finger. However, the finger shaped layout has the problems such as large drain area, high drain capacitance, poor dynamic characteristic, long polycrystalline silicon gate electrode resulting delay when turning on or turning off the device and so on. Furthermore, there is a right angle at the edge of the finger structure, which is easy to cause the curvature effect; the electric field is concentrated at the edge, thereby leading to the pre-breakdown of the device; and hot spots are easy to generate at the right angle, thereby affecting the safety operating area and the reliability of the device.

Therefore, in addition to the design of the device structure, the design of the device layout is very important. The present invention provides a method for designing a layout, which uses a grid structure to reduce the curvature effect of the finger structure, while reducing the drain area and improving the dynamic characteristics of the device. The geometric characteristic of the grid layout structure increases the width-to-length ratio of the device, increases the current per unit area, and is beneficial to the low voltage and high current fields.

In addition, compared with the Reduced Surface Field (RESURF) effect of the finger-shaped layout in a one-dimensional direction, the present invention assists in depletion of the drain region from a two-dimensional direction; furthermore, for the layout structure whose source electrodes are shared by two drain-electrodes-center's cells provided by the present invention, the electric field lines diverge outward from the center of the cell, and the static characteristic of the device is better. Therefore, compared with the traditional finger-shaped layout, the grid structure provided by the present invention can increase the concentration of the drift region, and therefore reduce the specific on-resistance of the device and increase the FOM of the device under the same withstand voltage.

However, due to the more concentrated current of the grid layout structure, more carriers are accumulated at the device's area closing to the drain region, thereby reducing the on-state breakdown voltage of the device and narrowing the safety operation region. To solve the above problems, the present invention provides a polygonal layout structure using a buffer layer structure. The reliability of the device is improved. The present invention further provides a terminal design, thereby avoiding the curvature effect introduced by the traditional terminal and further optimizing the performance of the device.

### SUMMARY

The present invention provides a lateral power semiconductor device layout and a device structure, and particularly relates to a lateral high-current power semiconductor device layout and a device structure. The technical problems to be solved by the present invention are: for the problems of high parasitic capacitance, non-uniform current and low current per unit area of a commonly used finger layout, meanwhile a method for designing a layout of a low-voltage and high-current lateral power semiconductor device is provided.

To achieve the aforementioned objective of the present invention, the technical solutions of the present invention are as follows:

I. A first objective of the present invention is to provide a lateral power semiconductor device layout and a device structure;

a drain electrode central square cell layout includes a source region, a gate electrode, a drain region, a drift region and a body region;

the body region and the source region are jointly integrated in cells to reduce the area of the device and increase the integrity;

the drain region is located at the center of the layout, the centers of the source region, the gate electrode and the drift region coincide with the center of the drain region, the drift region surrounds the drain region, the source region is tangent to an outer edge of the gate electrode, the body region is tangent to an inner edge and an outer edge of the source region, a length of the drift region is consistent with a length of the drift region of the device, a part of the gate electrode beyond an edge of the drift region serves as a field plate, and the static characteristic of the device is optimized;

the cells are closely arranged to form a corresponding device layout, and the cells of the device share the source region;

a drain electrode central cell is of a polygonal structure with the number of sides greater than or equal to 3 or a circle with the number of sides greater than or equal to 3, or the cells are integrated into an finger structure to increase a width-to-length ratio and improve the current capability of the device.

As a preferred manner, a drain electrode central cell layout is triangular, quadrilateral, pentagonal, hexagonal, circular or octagonal.

As a preferred manner, the length of the source region is half of a length dl of the source region in the device to increase the integrity, or is a length dl of the source region in the device to improve the overcurrent capability.

As a preferred manner, the drain electrode central cell is octagonal, and the punching area at a shared source region of four adjacent cells centers is increased, thereby meeting high-current application, reducing the area of the device and increasing the integrity.

As a preferred manner, the drain electrode central cell is circular, and adjacent columns of cells are staggered longitudinally and/or are staggered laterally, thereby increasing the integrity of the device and defining repeated units of the cells closely arranged longitudinally as a column.

II. A second objective of the present invention is to provide a lateral power semiconductor device layout structure;

a source electrode central square cell layout includes a source region, a gate electrode, a drain region, a drift region and a body region;

the body region is located at the center of the layout, the centers of the source region, the drain region, the gate electrode and the drift region coincide with the center of the body region, the source region is tangent to an outer edge of the body region, the gate electrode is tangent to an outer edge of the source region, the drift region is tangent to an inner edge of the drain region, a length of the drift region is consistent with a length of the drift region of the device, a part of the gate electrode beyond an edge of the drift region serves as a field plate, and the static characteristic of the device is optimized;

the cells are closely arranged to form a corresponding device layout, and the cells of the device share the drain region;

a source electrode central cell is of a polygonal structure with the number of sides greater than or equal to 3 or a circle, or the cells are integrated into an finger structure;

the square cells are closely arranged to form a corresponding device layout.

As a preferred manner, a source electrode central cell layout is triangular, quadrilateral, pentagonal, hexagonal, circular or octagonal.

As a preferred manner, the length of the source region is half of a length dl of the source region in the device to increase the integrity, or is a length dl of the source region in the device to improve the overcurrent capability.

As a preferred manner, the source electrode central cell is octagonal, and the punching area at a shared drain region of four adjacent cells centers is increased, thereby meeting high-current application, reducing the area of the device and increasing the integrity.

As a preferred manner, the source electrode central cell layout is circular, and adjacent columns of cells are staggered longitudinally and/or are staggered laterally, thereby increasing the integrity of the device and defining repeated units of the cells closely arranged longitudinally as a column.

III. A third objective of the present invention is to provide a lateral power semiconductor device structure using a buffer layer, using the high-current lateral power semiconductor device layout structure, and including:

a first conduction type substrate, where a second conduction type drift region and a first conduction type first body region are arranged on the substrate, a first conduction type second body region and a second conduction type source region are arranged in the first body region, a source electrode is arranged above the second conduction type source region, a second conduction type drain region and a second conduction type first buffer layer are arranged in the drift region, a drain electrode is arranged on the second conduction type drain region, and a left edge of the gate electrode is tangent to a right edge of the source region.

As a preferred manner, a second buffer layer is arranged in the drift region; in a case that a doping type of the second buffer layer is the same as a doping type of a first buffer layer, a thickness of the second buffer layer is greater than or less than a thickness of the first buffer layer; and in a case that the doping type of the second buffer layer is different from the doping type of the first buffer layer, the thickness of the second buffer layer is less than the thickness of the first buffer layer, and a Double-RESURF structure is formed, so that the breakdown voltage of the device is improved.

As a preferred manner, at least three buffer layers are arranged in the drift region to further optimize the static characteristic of the device;

or the static characteristic of the device is further optimized by combining the Double-RESURF structure and the buffer layer, thereby increasing the static optimal value of the device.

IV. A fourth objective of the present invention is to provide a lateral power semiconductor device structure with a terminal structure, using the high-current lateral power semiconductor device layout structure, and including:

a first conduction type substrate, where a second conduction type buried layer is arranged on the substrate, the buried layer is connected to a second conduction type first connection region, a second conduction type isolating structure potential second connection region is arranged in the first connection region, a second isolating structure electrode is arranged on the second connection region, a first conduction type substrate potential connection region is arranged in the substrate, a substrate electrode is arranged on the substrate potential, a first conduction type well is arranged on the buried layer, a first conduction type isolating structure potential first connection region and a second connection region in the first connection region are arranged in the well, a first isolating structure electrode is arranged on the second connection region in the well, a drift region and a first conduction type first body region are arranged in the well, a first conduction type second body region and a second conduction type source region are arranged in the first body region, a source electrode is arranged on the source region, a second conduction type drain region is arranged in the drift region, a drain electrode is arranged on the second conduction type drain region, a left edge of the gate electrode is tangent to a right edge of the source region, a field oxidation layer covers the surface of the whole device, a right edge of the SAB structure is tangent to a left edge of the drain region, a silicon local oxidation structure is located between the electrodes, and a first conduction type first isolating structure electrode is connected between the drain region and the second isolating structure electrode.

As a preferred manner, different voltage biases are applied to the drain region and the second isolating structure electrode, and a drain terminal bias is lower than a substrate bias, thereby meeting the requirements of the device under different working states.

As a preferred manner, a traditional right-angled terminal structure or a optimized terminal structure which alleviates the curvature effect with an optimized curvature effect is used, and the terminal structure with the optimized curvature effect comprises a terminal structure subjected to hexagonal, octagonal and circular processing at a corner.

The principle of the present invention is as follows:

In view of a device in FIG. 2A, a width-to-length ratio is 8/(In (b/a)); in view of a device in FIG. 3A, a width-to-length ratio is 4 \sqrt{3}/(In (b/a)); in view of a device in FIG. 4A, a width-to-length ratio is (8/(1+\sqrt{2}))/(In (b/a)); and in view of FIG. 5A, a width-to-length ratio is 2π/(In (b/a)). a is a distance from the center of the device to an edge of a gate electrode close to a drain region, and b is a distance from the center of the device to the edge of the gate electrode close to a source region.

In addition, the method for designing the layout provided by the present invention has good static characteristic. Taking FIG. 2A as an example, the drain region is located at the center and the electric field lines diverge outward from the drain region to avoid the concentration of the electric field lines, so the off-state voltage-resistant characteristic of the device is better; the difference is that the method for designing the traditional finger layout has the RESURF effect only in the horizontal direction, and the method for designing the layout provided by the present invention has the drift region in the vertical direction to reduce the peak electric field of the surface of the device in the two-dimensional direction, thereby improving the voltage-resistant capability of the device, and increasing the concentration of the drift region of the device and reducing the specific on-resistance of the device on the promise of not changing the voltage-resistant capability of the device. With the increased number of sides, the RESURF effect in the two-dimensional direction is enhanced, and the concentration of the electric field caused by the right-angle structure introduced by the square cell can be avoided. To solve the above problems, the present invention introduces the hexagonal structure as shown in FIG. 3A, the octagonal structure as shown in FIG. 4A and the circular structure in FIG. 5A, thereby further enhance the RESURF effect of the device, while reducing the curvature effect and optimizing the static characteristic of the device.

However, for the drain center structure, since electrons are aggregated from the low-voltage source electrode to the high-voltage drain electrode at the center, the current of the device close to the drain region is more concentrated and more carriers are accumulated in the on-state, thereby resulting in low on-state breakdown voltage of the device and narrow safety operation region. To improve the on-state voltage resistance of the device and the safety operation region of the device, as shown in FIG. 6A and FIG. 7A, the present invention provides two buffer layer structures to change the position where the peak value of the electric field occurs, thereby improving the on-state voltage resistance of the device, reducing the risk of easy breakdown of the device in the on-state and improving the reliability of the device.

In addition to designing the device as a drain center structure to optimize the characteristic, the present invention further provides a source center structure. The structure has the following characteristics: since the electric field lines are aggregated inward in an off-state, the off-state breakdown voltage of the device is low; and since the current diverges outwards in the on-state, the concentration of the carriers at the central position of the device is avoided, so that the on-state breakdown voltage of the device is high. By increasing the buffer layer structure, the voltage-resistant characteristic of the device is improved, and the requirement of some vehicle-mounted products on the static characteristic that the on-state breakdown voltage>the off-state breakdown voltage is realized.

In addition to optimizing and improving the static characteristic of the device, the present invention is further beneficial to the optimization of the dynamic characteristic of the device. Since the traditional finger layout is pressurized at two ends of the gate electrode, the device at the center of the layout is turned on slowly. Based on the method for designing the layout provided by the present invention and in combination with a multi-layer metal wiring technology, the gate electrode of each cell can be pressurized at the same time, thereby optimizing the dynamic characteristic of the device and reducing the delay time.

In a word, the present invention optimizes the dynamic and static characteristics of the device and can be applied to the design of the lateral power semiconductor device layout such as LDMOS and LIGBT.

The present invention has the following beneficial effects: the method for designing the layout provided by the present invention has the greatest advantage that compared with the finger device, the grid structure can increase the width-to-length ratio of the device on the premise of not increasing the area of the device and can increase the number of the cells within the limited chip area, thereby improving the current capability of the device for manufacturing the low-voltage high-current device.

### BRIEF DESCRIPTION OF THE DRAWINGS

FIG. 1A is a schematic structural diagram of a lateral power semiconductor device;

FIG. 1B is an finger cell layout of a lateral power semiconductor device;

FIG. 1C is a layout of a shared structure of a drain electrode center finger cell source electrode of a lateral power semiconductor device;

FIG. 1D is a shared finger cell layout of a drain electrode of a lateral power semiconductor device;

FIG. 1E is a shared finger device layout of a drain electrode of a lateral power semiconductor device;

FIG. 1F is a shared structure layout of a drain electrode center finger cell source electrode of a lateral power semiconductor device with high integrity;

FIG. 1G is a shared structure layout of a body electrode center finger cell drain electrode of a lateral power semiconductor device;

FIG. 1H is a source electrode center finger cell layout of a lateral power semiconductor device with high integrity;

FIG. 1I is a shared structure layout of a source electrode center finger cell drain electrode of a lateral power semiconductor device with high integrity;

FIG. 2A is a drain electrode center square cell layout of a lateral power semiconductor device with high integrity according to Embodiment 1;

FIG. 2B is a shared structure layout of a drain electrode center square cell source electrode of a lateral power semiconductor device with high integrity according to Embodiment 1;

FIG. 2C is a drain electrode center square cell layout of a lateral power semiconductor device according to Embodiment 1;

FIG. 2D is a shared structure layout of a drain electrode center square cell source electrode of a lateral power semiconductor device according to Embodiment 1;

FIG. 2E is a source electrode center square cell layout of a lateral power semiconductor device with high integrity according to Embodiment 2;

FIG. 2F is a shared structure layout of a source electrode center square cell drain electrode of a lateral power semiconductor device with high integrity according to Embodiment 2;

FIG. 2G is a source electrode center square cell layout of a lateral power semiconductor device according to Embodiment 2;

FIG. 2H is a shared structure layout of a source electrode center square cell drain electrode of a lateral power semiconductor device according to Embodiment 2;

FIG. 3A is a drain electrode center hexagonal cell layout of a lateral power semiconductor device with high integrity according to Embodiment 3;

FIG. 3B is a shared structure layout of a drain electrode center hexagonal cell source electrode of a lateral power semiconductor device with high integrity according to Embodiment 3;

FIG. 3C is a drain electrode center hexagonal cell layout of a lateral power semiconductor device according to Embodiment 3;

FIG. 3D is a shared structure layout of a drain electrode center hexagonal cell source electrode of a lateral power semiconductor device according to Embodiment 3;

FIG. 3E is a source electrode center hexagonal cell layout of a lateral power semiconductor device with high integrity according to Embodiment 4;

FIG. 3F is a shared structure layout of a source electrode center hexagonal cell drain electrode of a lateral power semiconductor device with high integrity according to Embodiment 4;

FIG. 3G is a source electrode center hexagonal cell layout of a lateral power semiconductor device beneficial to high-current application according to Embodiment 4;

FIG. 3H is a shared structure layout of a source electrode center hexagonal cell drain electrode of a lateral power semiconductor device beneficial to high-current application according to Embodiment 4;

FIG. 4A is a drain electrode center octagonal cell layout of a lateral power semiconductor device with high integrity according to Embodiment 5;

FIG. 4B is a shared structure layout of a drain electrode center octagonal cell source electrode of a lateral power semiconductor device with high integrity according to Embodiment 5;

FIG. 4C is a drain electrode center octagonal cell layout of a lateral power semiconductor device beneficial to high-current application according to Embodiment 5;

FIG. 4D is a shared structure layout of a drain electrode center octagonal cell source electrode of a lateral power semiconductor device beneficial to high-current application according to Embodiment 5;

FIG. 4E is a drain electrode center octagonal cell layout of a lateral power semiconductor device with high integrity according to Embodiment 6;

FIG. 4F is a shared structure layout of a drain electrode center octagonal cell source electrode of a lateral power semiconductor device with high integrity according to Embodiment 6;

FIG. 4G is a source electrode center octagonal cell layout of a lateral power semiconductor device beneficial to high-current application according to Embodiment 7;

FIG. 4H is a shared structure layout of a source electrode center octagonal cell drain electrode of a lateral power semiconductor device beneficial to high-current application according to Embodiment 7;

FIG. 4I is a source electrode center octagonal cell layout of a lateral power semiconductor device according to Embodiment 7;

FIG. 4J is a shared structure layout of a source electrode center octagonal cell drain electrode of a lateral power semiconductor device according to Embodiment 7;

FIG. 5A is a drain electrode center circular cell layout of a lateral power semiconductor device with high integrity according to Embodiment 8;

FIG. 5B is a shared structure layout of a drain electrode center circular cell source electrode of a lateral power semiconductor device with high integrity according to Embodiment 8;

FIG. 5C is a drain electrode center circular cell layout of a lateral power semiconductor device beneficial to high-current application according to Embodiment 8;

FIG. 5D is a shared structure layout of a drain electrode center circular cell source electrode of a lateral power semiconductor device beneficial to high-current application according to Embodiment 8;

FIG. 5E is a drain electrode center circular cell layout of a lateral power semiconductor device beneficial to high-current application according to Embodiment 9;

FIG. 5F is a shared structure layout of a drain electrode center circular cell source electrode of a lateral power semiconductor device beneficial to high-current application according to Embodiment 9;

FIG. 5G is a source electrode center circular cell layout of a lateral power semiconductor device with high integrity according to Embodiment 10;

FIG. 5H is a shared structure layout of a source electrode center circular cell drain electrode of a lateral power semiconductor device with high integrity according to Embodiment 10;

FIG. 5I is a source electrode center circular cell layout of a lateral power semiconductor device beneficial to high-current application according to Embodiment 10;

FIG. 5J is a shared structure layout of a source electrode center circular cell drain electrode of a lateral power semiconductor device beneficial to high-current application according to Embodiment 10;

FIG. 6A is a structural schematic diagram of a lateral power semiconductor device using a single buffer layer according to Embodiment 11;

FIG. 6B is a drain electrode center square cell layout of a lateral power semiconductor device with high integrity and using a single buffer layer according to Embodiment 11;

FIG. 6C is a shared structure layout of a drain electrode center square cell source electrode of a lateral power semiconductor device with high integrity and using a single buffer layer according to Embodiment 11;

FIG. 6D is a source electrode center square cell layout of a lateral power semiconductor device with high integrity and using a single buffer layer according to Embodiment 11;

FIG. 6E is a shared structure layout of a source electrode center square cell drain electrode of a lateral power semiconductor device with high integrity and using a single buffer layer according to Embodiment 11;

FIG. 6F is a drain electrode center hexagonal cell layout of a lateral power semiconductor device with high integrity and using a single buffer layer according to Embodiment 11;

FIG. 6G is a shared layout of a drain electrode center hexagonal cell source electrode of a lateral power semiconductor device with high integrity and using a single buffer layer according to Embodiment 11;

FIG. 6H is a source electrode center hexagonal cell layout of a lateral power semiconductor device with high integrity and using a single buffer layer according to Embodiment 11;

FIG. 6I is a shared structure layout of a source electrode center hexagonal cell drain electrode of a lateral power semiconductor device with high integrity and using a single buffer layer according to Embodiment 11;

FIG. 6J is a drain electrode center hexagonal cell layout of a lateral power semiconductor device with high integrity and using a single buffer layer according to Embodiment 11;

FIG. 6K is a shared structure layout of a drain electrode center hexagonal cell source electrode of a lateral power semiconductor device with high integrity and using a single buffer layer according to Embodiment 11;

FIG. 6L is a source electrode center hexagonal cell layout of a lateral power semiconductor device with high integrity and using a single buffer layer according to Embodiment 11;

FIG. 6M is a shared structure layout of a source electrode center octagonal cell drain electrode of a lateral power semiconductor device with high integrity and using a single buffer layer according to Embodiment 11;

FIG. 6N is a drain electrode center circular cell layout of a lateral power semiconductor device with high integrity and using a single buffer layer according to Embodiment 11;

FIG. 6O is a shared structure layout of a drain electrode center circular cell source electrode of a lateral power semiconductor device with high integrity and using a single buffer layer according to Embodiment 11;

FIG. 6P is a source electrode center circular cell layout of a lateral power semiconductor device with high integrity and using a single buffer layer according to Embodiment 11;

FIG. 6Q is a shared structure layout of a source electrode center circular cell drain electrode of a lateral power semiconductor device with high integrity and using a single buffer layer according to Embodiment 11;

FIG. 7A is a structural schematic diagram of a lateral power semiconductor device using a stepped buffer layer according to Embodiment 12;

FIG. 7B is a drain electrode center square cell layout of a lateral power semiconductor device with high integrity and using a stepped buffer layer according to Embodiment 12;

FIG. 7C is a shared structure layout of a drain electrode center square cell source electrode of a lateral power semiconductor device with high integrity and using a stepped buffer layer according to Embodiment 12;

FIG. 7D is a source electrode center square cell layout of a lateral power semiconductor device with high integrity and using a stepped buffer layer according to Embodiment 12;

FIG. 7E is a shared structure layout of a source electrode center square cell drain electrode of a lateral power semiconductor device with high integrity and using a stepped buffer layer according to Embodiment 12;

FIG. 7F is a drain electrode center hexagonal cell layout of a lateral power semiconductor device with high integrity and using a stepped buffer layer according to Embodiment 12;

FIG. 7G is a shared structure layout of a drain electrode center hexagonal cell source electrode of a lateral power semiconductor device with high integrity and using a stepped buffer layer according to Embodiment 12;

FIG. 7H is a source electrode center hexagonal cell layout of a lateral power semiconductor device with high integrity and using a stepped buffer layer according to Embodiment 12;

FIG. 7I is a shared structure layout of a source electrode center hexagonal cell drain electrode of a lateral power semiconductor device with high integrity and using a stepped buffer layer according to Embodiment 12;

FIG. 7J is a drain electrode center octagonal cell layout of a lateral power semiconductor device with high integrity and using a stepped buffer layer according to Embodiment 12;

FIG. 7K is a shared structure layout of a drain electrode center octagonal cell source electrode of a lateral power semiconductor device with high integrity and using a stepped buffer layer according to Embodiment 12;

FIG. 7L is a source electrode center octagonal cell layout of a lateral power semiconductor device with high integrity and using a stepped buffer layer according to Embodiment 12;

FIG. 7M is a shared structure layout of a source electrode center octagonal cell drain electrode of a lateral power semiconductor device with high integrity and using a stepped buffer layer according to Embodiment 12;

FIG. 7N is a drain electrode center circular cell layout of a lateral power semiconductor device with high integrity and using a stepped buffer layer according to Embodiment 12;

FIG. 7O is a shared structure layout of a drain electrode center circular cell source electrode of a lateral power semiconductor device with high integrity and using a stepped buffer layer according to Embodiment 12;

FIG. 7P is a source electrode center circular cell layout of a lateral power semiconductor device with high integrity and using a stepped buffer layer according to Embodiment 12;

FIG. 7Q is a shared structure layout of a source electrode center circular cell drain electrode of a lateral power semiconductor device with high integrity and using a stepped buffer layer according to Embodiment 12;

FIG. 8A is a schematic structural diagram of a lateral power semiconductor device with a terminal structure according to Embodiment 13;

FIG. 8B is a shared layout structure of a drain electrode center finger cell source electrode of a lateral power semiconductor device with a traditional terminal structure according to Embodiment 13;

FIG. 8C is a shared structure layout of a drain electrode center square cell source electrode of a lateral power semiconductor device with a terminal structure with additional curvature design according to Embodiment 13;

FIG. 8D is a shared structure layout of a drain electrode center hexagonal cell source electrode of a lateral power semiconductor device with a terminal structure with additional curvature design according to Embodiment 13;

FIG. 8E is a shared structure layout of a drain electrode center octagonal cell source electrode of a lateral power semiconductor device with a terminal structure with additional curvature design according to Embodiment 13;and

FIG. 8F is a shared structure layout of a drain electrode center circular cell source electrode of a lateral power semiconductor device with a terminal structure with additional curvature design according to Embodiment 13.

For Embodiment 1 and Embodiment 2, 201 is a source region, 202 is a gate electrode, 203 is a drain region, 204 is a drift region, and 205 is a body region. A length d₁ of the source region, a length d₂ of the gate electrode, a length d₃ of the drain region and a length d₄ of the drift region are kept consistent with sizes d₁-d₄ of the device in Embodiment 1.

For Embodiment 3 and Embodiment 4, 301 is a source region, 302 is a gate electrode, 303 is a drain region, 304 is a drift region, and 305 is a body region. A length d₁ of the source region, a length d₂ of the gate electrode, a length d₃ of the drain region and a length d₄ of the drift region are consistent with sizes d₁-d₄ of the device in Embodiment 1.

For Embodiments 5-7, 401 is a source region, 402 is a gate electrode, 403 is a drain region, 404 is a drift region, and 405 is a body region. A length d₁ of the source region, a length d₂ of the gate electrode, a length d₃ of the drain region and a length d₄ of the drift region are consistent with sizes d₁-d₄ of the device in Embodiment 1.

For Embodiments 8-10, 501 is a source region, 502 is a gate electrode, 503 is a drain region, 504 is a drift region, and 505 is a body region. A length d₁ of the source region, a length d₂ of the gate electrode, a length d₃ of the drain region and a length d₄ of the drift region are kept consistent with sizes d₁-d₄ of the device in Embodiment 1.

For Embodiment 11, 607 is a first conduction type substrate, a second conduction type drift region 604 and a first conduction type first body region 606 are arranged on the substrate 607, a first conduction type second body region 605 and a second conduction type source region 601 are arranged in the first body region 606, and a second conduction type drain region 603 and a second conduction type buffer layer region 611 are arranged in the drift region 604. 602 is a gate electrode, 608 is a source electrode, 609 is a drain electrode, and 610 is a field oxidation layer. d1₁ is a length of the source region, d₂ is a length of the gate electrode, d₃ is a length of the drain region, d₄ is a length of the drift region, and d₅ is a length of the buffer layer beyond the drain region.

For Embodiment 12, 707 is a first conduction type substrate, a second conduction type drift region 704 and a first conduction type first body region 706 are arranged on the substrate 707, a first conduction type second body region 705 and a second conduction type source region 701 are arranged in the first body region 706, and a second conduction type drain region 703, a second conduction type buffer layer region 711 and a second buffer layer 712 are arranged in the drift region 704. 702 is a gate electrode, 708 is a source electrode, 709 is a drain electrode, and 710 is a field oxidation layer. d1₁ is a length of the source region, d₂ is a length of the gate electrode, d₃ is a length of the drain region, d₄ is a length of the drift region, d₅ is a length of the buffer layer beyond the drain region, and d₆ is a length of the second buffer layer beyond the drain region.

For Embodiment 13, a first conduction type substrate 807, where a second conduction type buried layer 821 is arranged on the substrate 807, the buried layer 821 is connected to a second conduction type first connection region 819, a second conduction type isolating structure potential second connection region 816 is arranged in the first connection region 819, a second isolating structure electrode 812 is arranged on the second connection region 816, a first conduction type substrate potential connection region 817 is arranged in the substrate 807, a substrate electrode 813 is arranged on a substrate potential 817, a first conduction type well 820 is arranged on the buried layer 821, a first conduction type isolating structure potential first connection region 818 and a second connection region 815 in the first connection region 818 are arranged in the well 820, a first isolating structure electrode 811 is arranged on the second connection region 815 in the well, a drift region 804 and a first conduction type first body region 806 are arranged in the well, a first conduction type second body region 805 and a second conduction type resource region 801 are arranged in the first body region 806, a source electrode 808 is arranged on the source region 801, a second conduction type drain region 803 is arranged in the drift region 804, a drain electrode 809 is arranged on the second conduction type drain region 803, a left edge of the gate electrode 802 is tangent to a right edge of the source region 801, a field oxidation layer 810 covers a surface of the whole device, a right edge of the SAB structure 814 is tangent to a left edge of the drain region, a silicon local oxidation structure 822 is located between the electrodes, and a first conduction type first isolating structure electrode 811 is connected between the drain region 803 and the second isolating structure electrode 812. d₁ is a length of the source region, d₂ is a length of the gate electrode, d₃ is a length of the drain region, d₄ is a length of the drift region, d₇ is a distance between the drain region and a first isolating region, d₈ is a width of the first isolating region, d₉ is a distance between the first isolating region and a second isolating region, d₁₀ is a width of the second isolating region, d₁₁ is a distance between the second isolating region and the substrate potential connection region, and d₁₂ is a width of the substrate potential connection region.

### DETAILED DESCRIPTION OF THE EMBODIMENTS

To make the problems to be solved, solutions and positive effects of the present invention more clearly, the present invention will be further described with reference to the accompanying drawings.

The specific implementation manners of the present invention are described below through the specific examples, and relevant technicians may understand the advantages and the application manner of the structure of the present invention through the specification. The structure of the present invention may be subjected to detailed processing and modified change as long as the principle of the present invention is not violated.

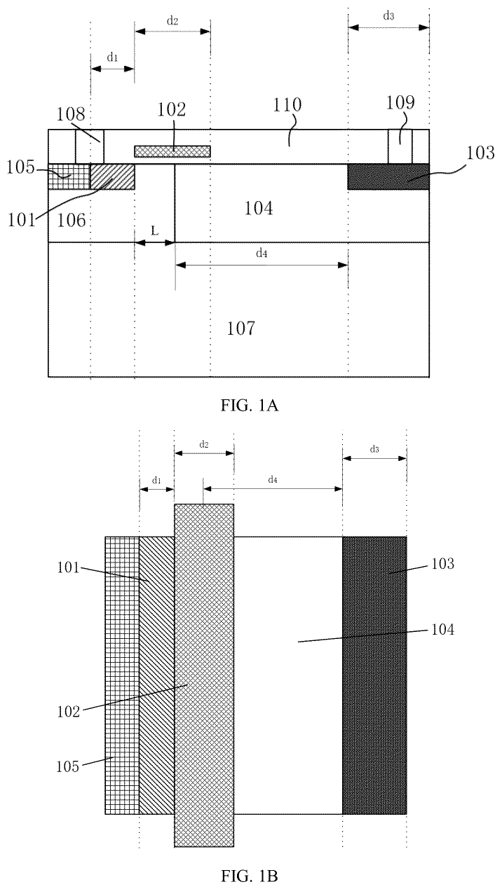

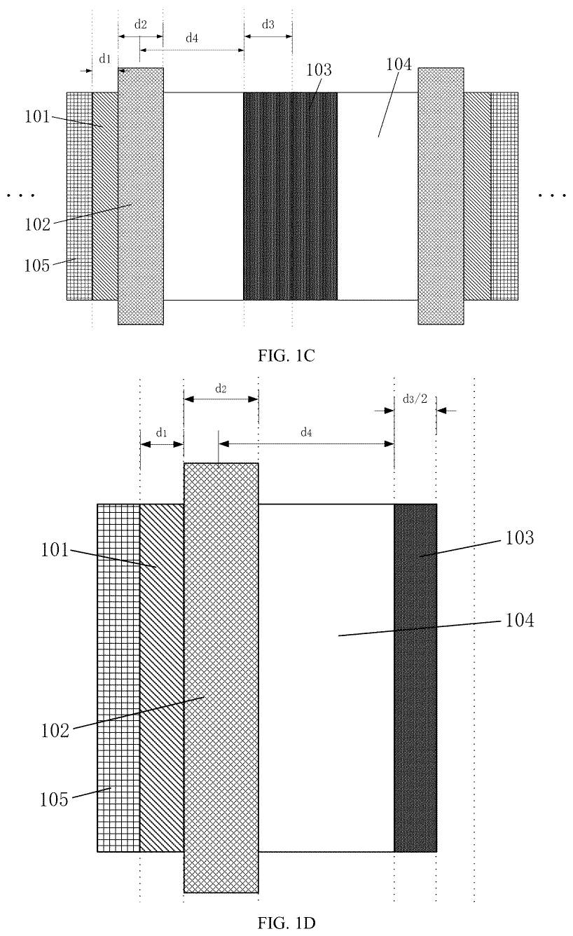

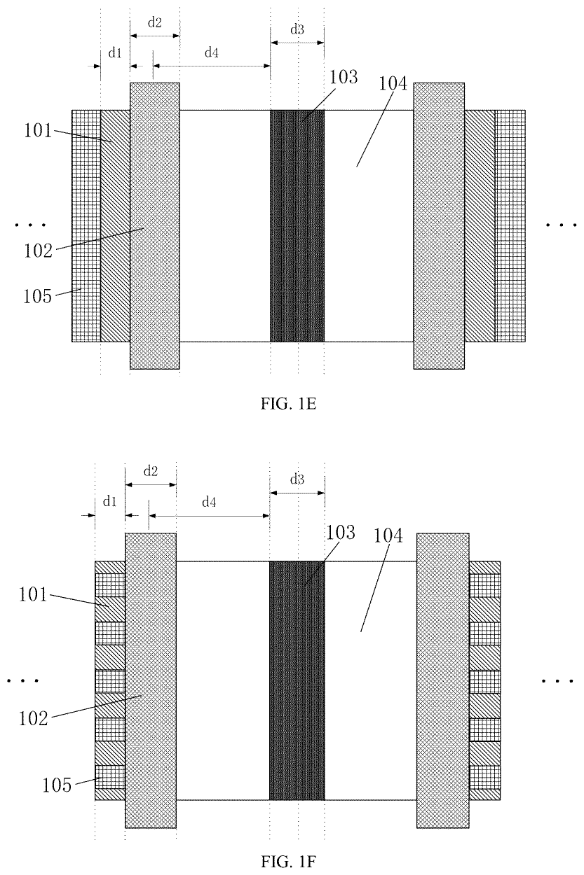

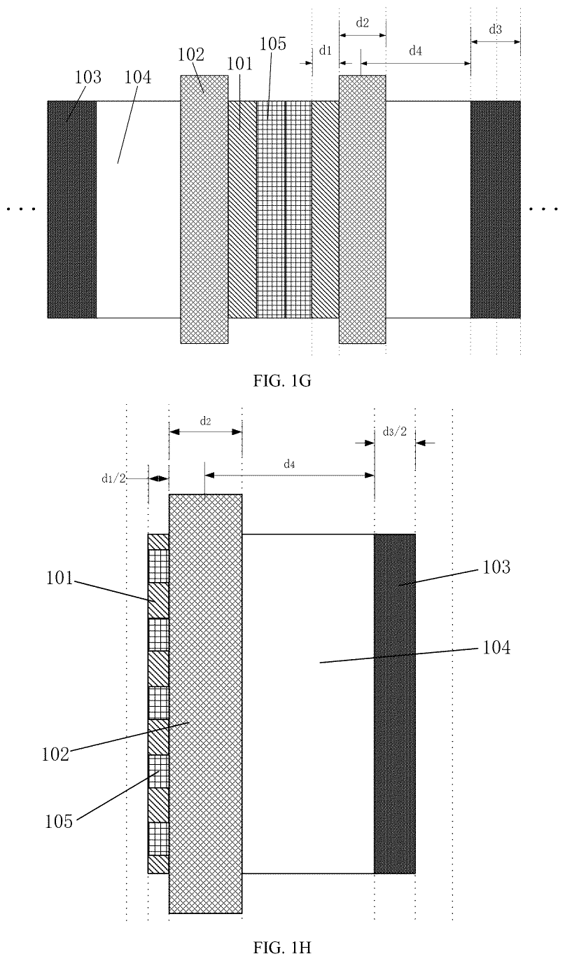

As shown in FIG. 1A, this is a typical LDMOS structure. In FIG. 1A to FIG. 11, 101 is a source region, 102 is a gate electrode, 103 is a drain region, 104 is a drift region, 105 is a second body region, 106 is a first body region, 107 is a first conduction type substrate, 108 is a source electrode, 109 is a drain electrode, and 110 is a field oxidation layer.

A second conduction type drift region 104 and a first conduction type first body region are arranged on the substrate 107, a first conduction type second body region 105 and a second conduction type source region 101 are arranged in the first body region 106, and a second conduction type drain region 103 is arranged in the drift region 104. d1₁ is a length of the source region, d₂ is a length of the gate electrode, d₃ is a length of the drain region, and d₄ is a length of the drift region. L is a length of a channel.

As shown in FIG. 1B, it is a typical finger cell layout corresponding to FIG. 1A. In FIG. 1A, a drain center structure device layout formed by the cell is shown in FIG. 1C. The drain region is shared by two devices, so as shown in FIG. 1D, the length of the drain region of the cell layout is reduced to ½ of the original length, a device layout as shown in FIG. 1E is formed, and the integrity of the layout is higher than that of FIG. 1C.

However, separately leading out the body region is a waste of area in the process of designing the actual power device layout. To reduce the waste of the area, the layout design method as shown in FIG. 1F is often used for integrating the body region into the source region to be grounded uniformly, and the structure is a drain center structure layout with the highest integrity.

As shown in FIG. 1G, it is a source center device layout formed by a cell in FIG. 1B. However, the integrity of the layout is low, and according to the design idea of FIG. 1D, the length of the source region of the cell is reduced to ½ of the original length, as shown in FIG. 1H. The device formed by the cell is shown in FIG. 1I. The structure increases the integrity of the device by sharing the source and drain regions.

In view of the above method for designing the layout and to increase the current of the device, it is necessary to increase the length of the cell, thereby increasing the width-to-length ratio of the device. However, for the overlong device which has the disadvantages of non-uniform flow and late starting of the device, the reliability of the device during use is affected. To increase the width-to-length ratio of the device and the current capability of the device within the limited area, and improve the reliability of the device, the present invention provides the following embodiments.

In the following embodiments, a material of an oxidation layer may be a grid oxidation layer or a high dielectric constant material.

The gate electrode may be metal, or may be polycrystalline silicon.

A first conduction type is P-type doping and a second conduction type is N-type doping; or a first conduction type is N-type doping and a second conduction type is P-type doping. The following embodiments are described according to the fact that the first conduction type is P-type doping and the second conduction type is N-type doping.

### Embodiment 1

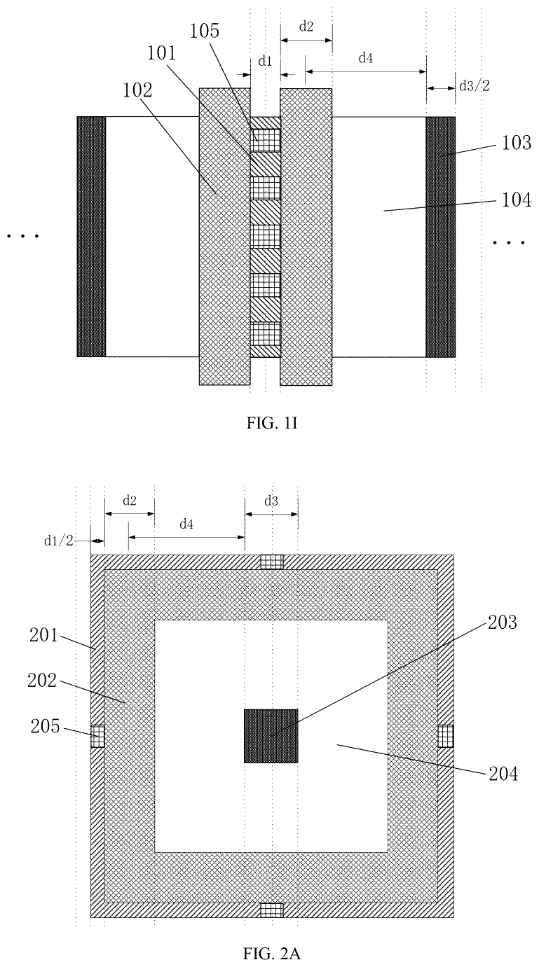

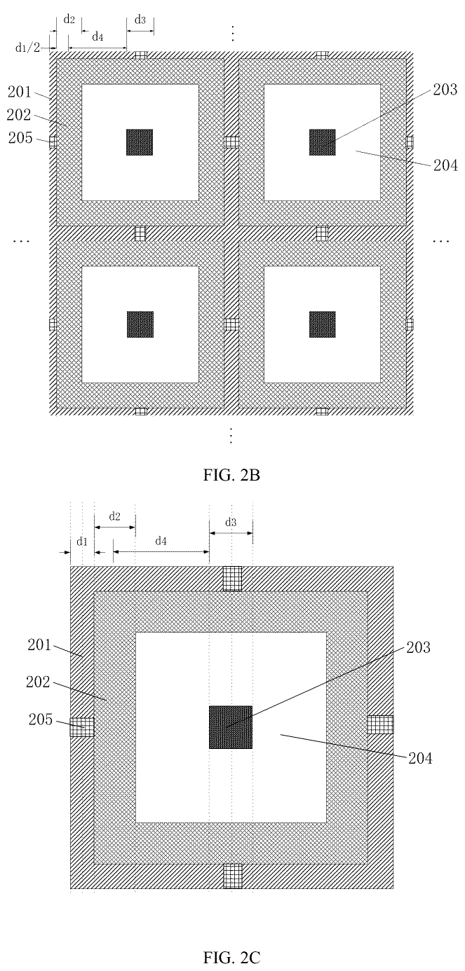

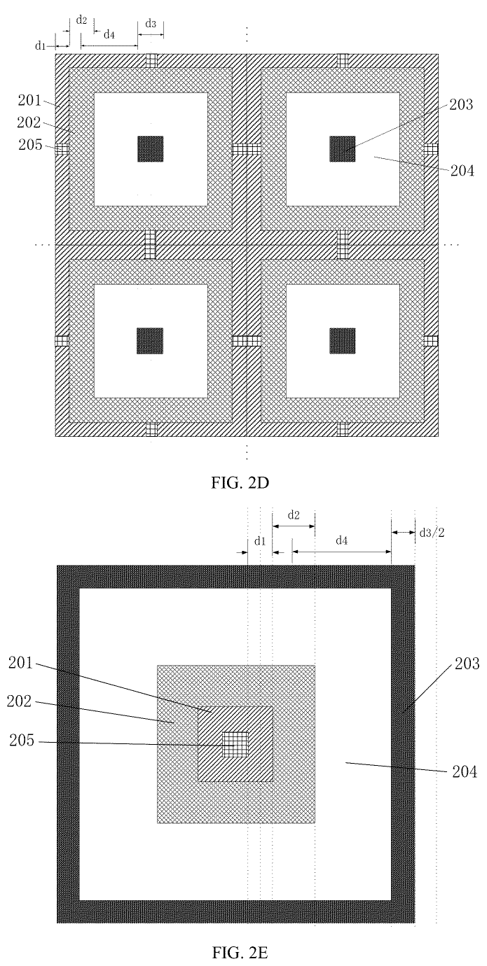

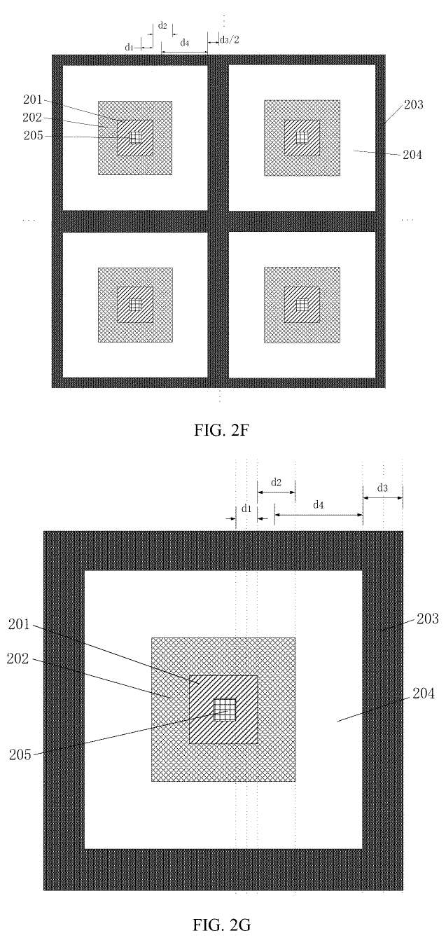

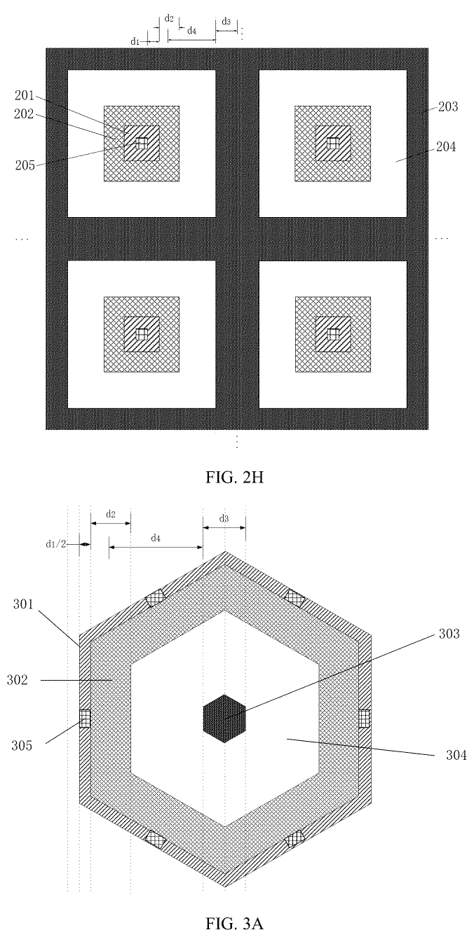

For Embodiment 1, as shown in FIG. 2A which is a drain electrode center square cell layout of a lateral power semiconductor device with high integrity, 201 is a source region, 202 is a gate electrode, 203 is a drain region, 204 is a drift region, and 205 is a body region. A length d₁ of the source region, a length d₂ of the gate electrode, a length d₃ of the drain region and a length d₄ of the drift region are kept consistent with sizes d₁-d₄ of the device in FIG. 1A. FIG. 2B is a device layout formed by a cell in FIG. 2A.

The body region and the source region are jointly integrated in cells to reduce the area of the device and increase the integrity;

the drain region 201 is located at the center of the layout, the centers of the source region 201, the gate electrode 202 and the drift region 204 coincide with the center of the drain region 203, the drift region 204 surrounds the drain region 203, the source region 201 is tangent to an outer edge of the gate electrode 202, the body region 205 is tangent to an inner edge and an outer edge of the source region 201, a length of the source region 201 is consistent with a length of the drift region of the device, a part of the gate electrode 202 beyond an edge of the drift region 204 serve as a field plate, and the static characteristic of the device is optimized; and

the cells are closely arranged to form a corresponding device layout, and the cells of the device share the source region.

This embodiment has the following advantages: the width-to-length ratio of a rectangular cell is large, so that the output current of the device can be increased within limited area, thereby improving the current capability of the device; in addition, this structure has RESURF effect in a two-dimensional direction, and since an electric field line diverges from inside to outside, this layout structure has higher breakdown voltage under the same size; compared with the finger structure in FIG. 1, the doping concentration of the device can be further increased, and the specific on-resistance of the device and the power consumption can be reduced; in addition, referring to the design ideal in FIG. 1H, the length of the source is reduced to ½ of the original length, thereby increasing the integrity of the device.

Considering the requirement of some devices on the flow size, this embodiment provides a cell layout as shown in FIG. 2C and a device layout as shown in FIG. 2D, the length of the source region maintains the original size design, and the punching of the source region can be increased to meet the high-current requirement.

### Embodiment 2

For Embodiment 2, as shown in FIG. 2E which is a source electrode center square cell layout of a lateral power semiconductor device with high integrity, 201 is a source region, 202 is a gate electrode, 203 is a drain region, 204 is a drift region, and 205 is a body region. A length d₁ of the source region, a length d₂ of the gate electrode, a length d₃ of the drain region and a length d₄ of the drift region are consistent with sizes d₁-d₄ of the device in FIG. 1A. FIG. 2F is a device layout formed by a cell in FIG. 2E.

The body region 205 is located at the center of the layout, the centers of the source region 201, the drain region 203, the gate electrode 202 and the drift region 204 coincide with the center of the body region 205, the source region 201 is tangent to an outer edge of the body region 205, the gate electrode 202 is tangent to an outer edge of the source region 201, the drift region 204 is tangent to an inner edge of the drain region 201, a length of the drift region 204 is consistent with a length of the drift region of the device, a part of the gate electrode 202 beyond an edge of the drift region 204 serves as a field plate, and the static characteristic of the device is optimized;

the cells are closely arranged to form a corresponding device layout, and the cells of the device share the drain region;

a source electrode central cell is of a polygonal structure or a circle with the number of sides greater than or equal to 3, or the cells are integrated into an finger structure; and the square cells are closely arranged to form a corresponding device layout.

This embodiment has the following advantages: since the source region is located at the center, the current can be prevented from being concentrated at the center of the device, thereby improving the on-state reliability and achieving higher on-state breakdown voltage. Some vehicle-mounted products have higher requirements on the safety operation region of the device, and this embodiment can meet this requirement.

Similarly, considering the high-current requirement, this embodiment provides a cell layout as shown in FIG. 2G and a corresponding device layout as shown in FIG. 2H. The length of the drain region maintains the original size design, the punching of the drain region can be increased, thereby meeting the high-current requirement.

### Embodiment 3

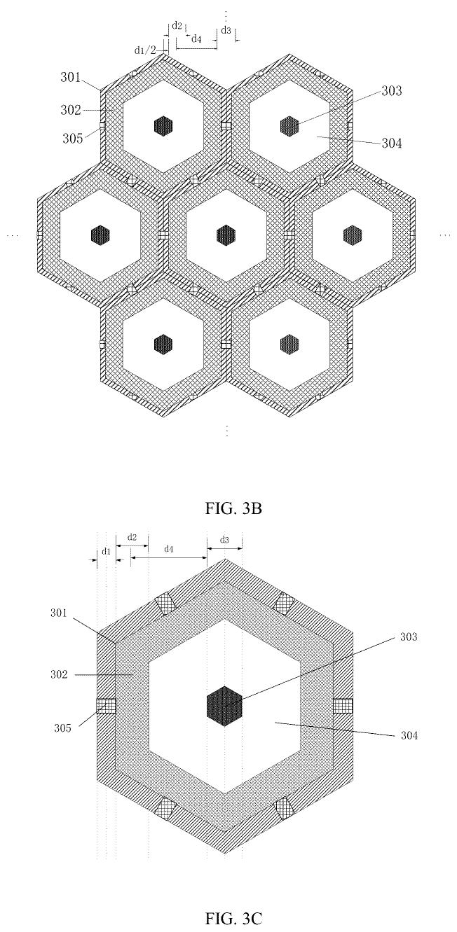

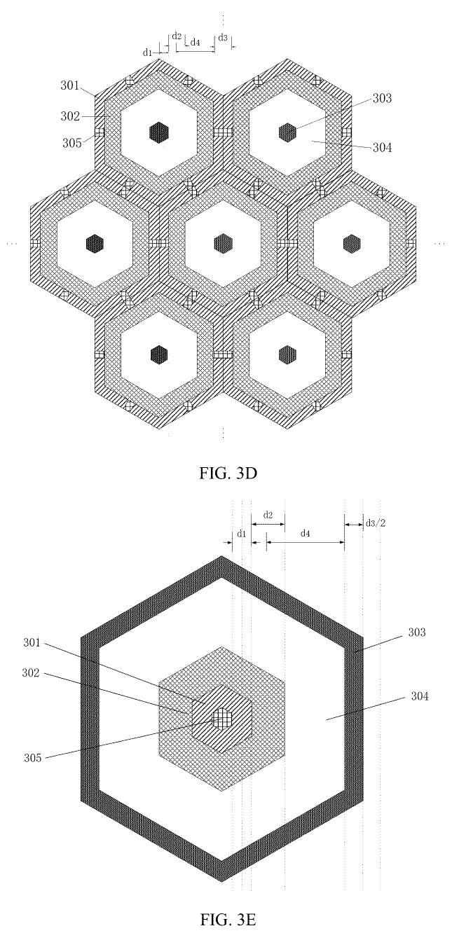

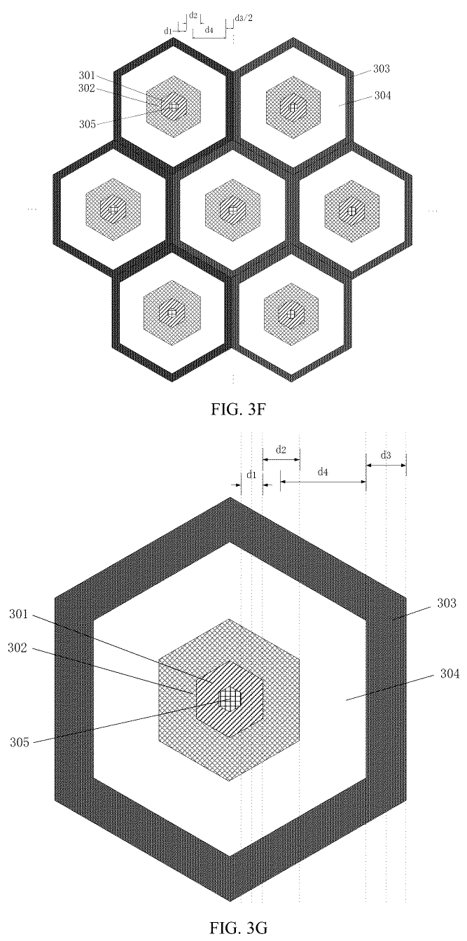

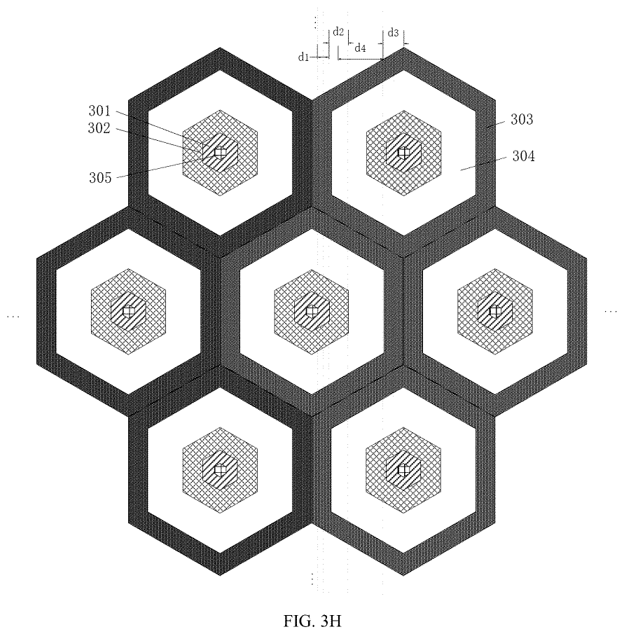

For Embodiment 3, as shown in FIG. 3A which is a drain electrode center hexagonal cell layout of a lateral power semiconductor device with high integrity, this embodiment is different from Embodiment 1 in that: the drain electrode center cell layout is hexagonal.

301 is a source region, 302 is a gate electrode, 303 is a drain region, 304 is a drift region, and 305 is a body region. A length d₁ of the source region, a length d₂ of the gate electrode, a length d₃ of the drain region and a length d₄ of the drift region are consistent with sizes d₁-d₄ of the device in FIG. 1A. FIG. 3B is a device layout formed by a cell in FIG. 2A.

In Embodiment 1, due to the presence of a 90° angle, the concentration of the electric field is easily caused, thereby affecting the reliability of the device. Compared with Embodiment 1, this embodiment reduces the influence of the curvature effect. In addition, this embodiment assists in depletion from three directions, so that the RESURF effect is more remarkable, which is more helpful for improving the reliability of the device.

Similarly, this embodiment provides a cell layout as shown in FIG. 3C and a corresponding device layout as shown in FIG. 2D, the length of the source region maintains the original size design, and the punching of the source region can be increased to meet the high-current requirement.

### Embodiment 4

For Embodiment 4, as shown in FIG. 3E which is a source electrode center hexagonal cell layout of a lateral power semiconductor device with high integrity, this embodiment is different from Embodiment 2 in that: the source electrode center cell layout is hexagonal.

301 is a source region, 302 is a gate electrode, 303 is a drain region, 304 is a drift region, and 305 is a body region. A length d₁ of the source region, a length d₂ of the gate electrode, a length d₃ of the drain region and a length d₄ of the drift region are kept consistent with sizes d₁-d₄ of the device in FIG. 1A. FIG. 2F is a device layout formed by a cell in FIG. 2E.

This embodiment provides a cell layout as shown in FIG. 3G and a corresponding device layout as shown in FIG. 2H, the length of the source region maintains the original size design, and the punching of the source region can be increased to meet the high-current requirement. Similarly, this embodiment also has the advantages of improving the safety operation region and meeting the vehicle-mounted requirement.

### Embodiment 5

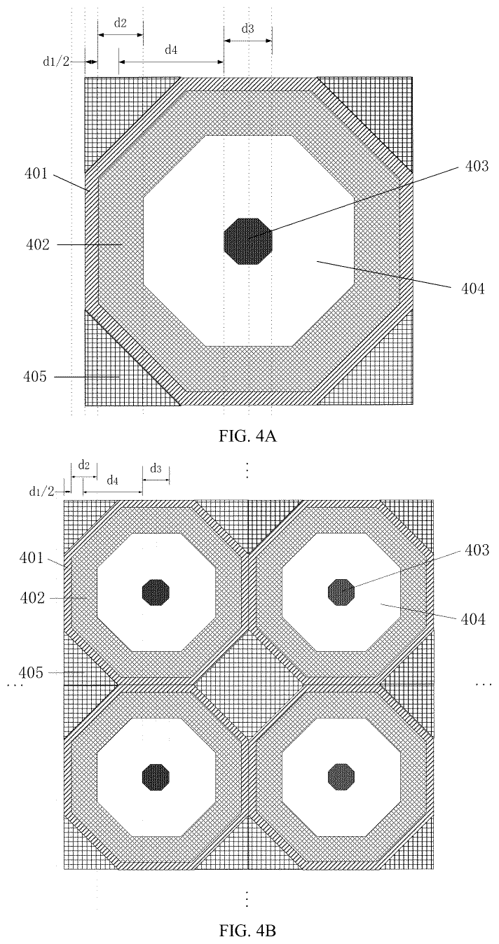

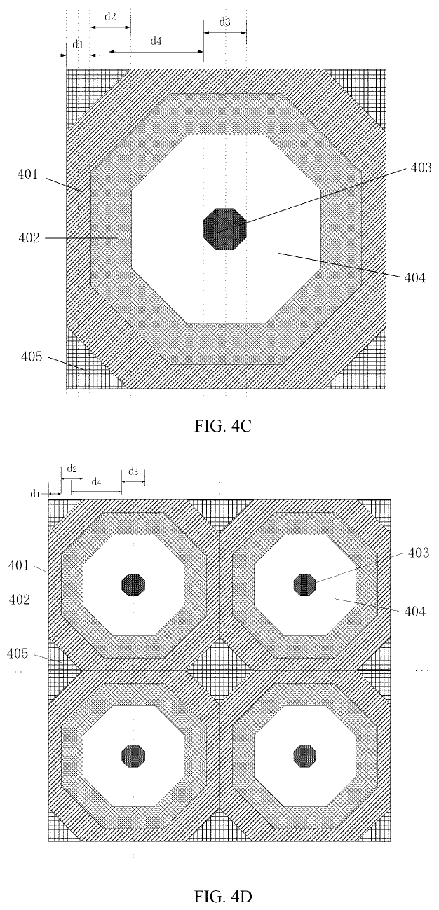

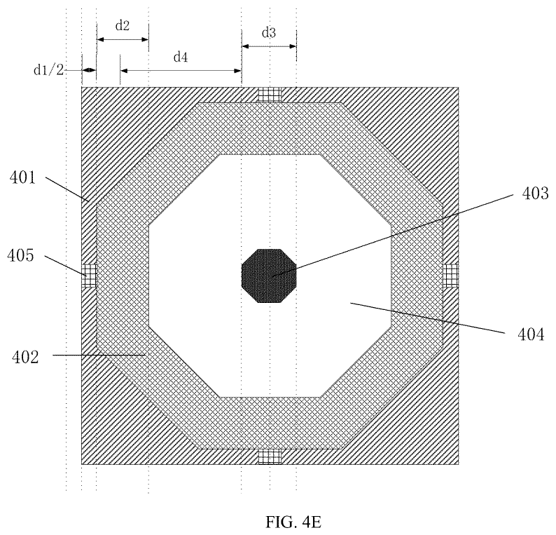

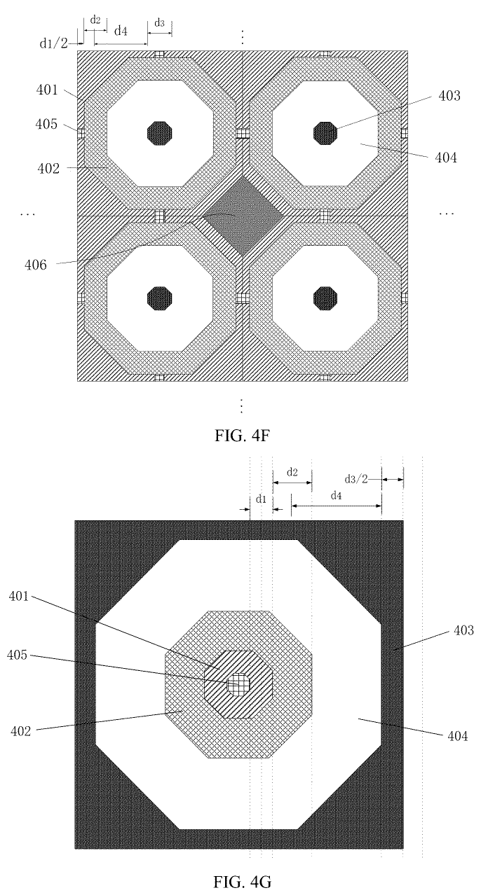

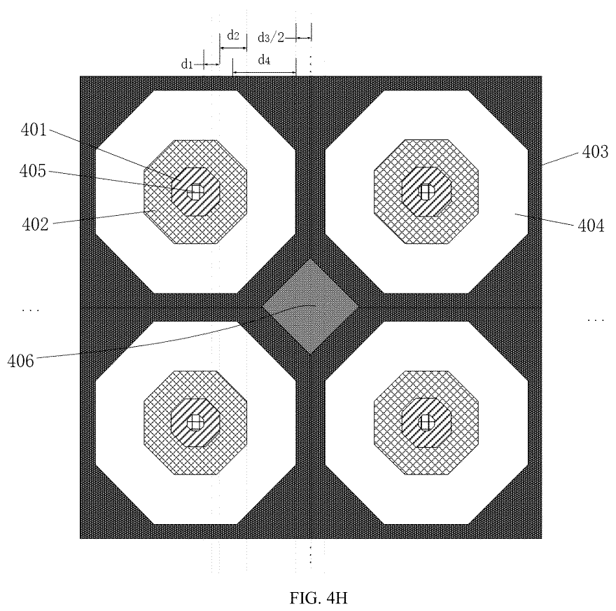

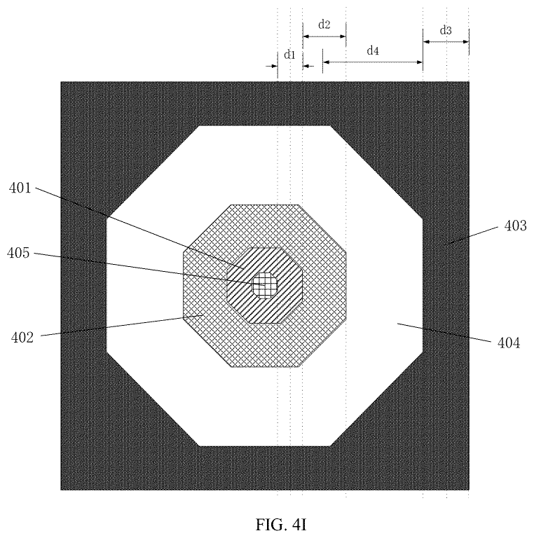

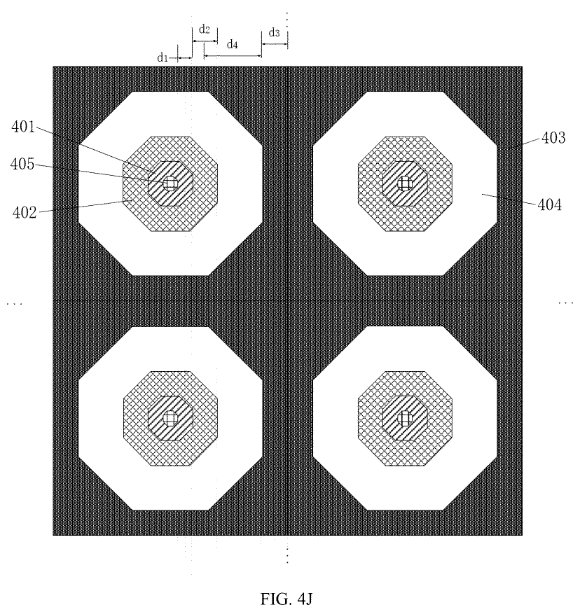

For Embodiment 5, as shown in FIG. 4A which is a drain electrode center octagonal cell layout of a lateral power semiconductor device with high integrity, this embodiment is different from Embodiment 1 in that: the drain electrode center cell layout is octagonal.

401 is a source region, 402 is a gate electrode, 403 is a drain region, 404 is a drift region, and 405 is a body region. A length d₁ of the source region, a length d₂ of the gate electrode, a length d₃ of the drain region and a length d₄ of the drift region are kept consistent with sizes d₁-d₄ of the device in FIG. 1A. FIG. 4B is a device layout formed by a cell in FIG. 4A.

This embodiment has the following advantages: the 135° treated design is used at the corner of the cell, thereby further avoiding the curvature effect and improving the reliability of the device; and the body region is integrated at the edge, so that the area utilization ratio of the device and the integrity of the device are increased.

Similarly, this embodiment provides a cell layout as shown in FIG. 4C and a corresponding device layout as shown in FIG. 4D, the length of the source region maintains the original size design, and the punching of the source region can be increased to meet the high-current requirement.

### Embodiment 6

For Embodiment 6, as shown in FIG. 4E which is a drain electrode center octagonal cell layout of a lateral power semiconductor device with high integrity, this embodiment is different from Embodiment 5 in that: the punching area at the shared source region of the centers of four adjacent cells, thereby meeting the high-current application, reducing the area of the device and increasing the integrity.

401 is a source region, 402 is a gate electrode, 403 is a drain region, 404 is a drift region, 405 is a body region, and 406 is a part of source electrode metal. A length d1 of the source region, a length d2 of the gate electrode, a length d3 of the drain region and a length d4 of the drift region are kept consistent with sizes d1-d4 of the device in FIG. 1A. FIG. 4F is a device layout formed by a cell in FIG. 4E.

This embodiment has the following advantages: compared with Embodiment 5 in which an edge is set as a body region, this embodiment integrates the body region in a cell, and sets an edge region as a source region and is connected to metal, thereby improving the flow capability of the device, further meeting the high-current requirement and improving the reliability of the device.

### Embodiment 7

For Embodiment 7, as shown in FIG. 4G which is a source electrode center octagonal cell layout of a lateral power semiconductor device with high integrity, this embodiment is different from Embodiment 2 in that: the source electrode center cell layout is octagonal.

401 is a source region, 402 is a gate electrode, 403 is a drain region, 404 is a drift region, and 405 is a body region. A length d₁ of the source region, a length d₂ of the gate electrode, a length d₃ of the drain region and a length d₄ of the drift region are kept consistent with sizes d₁-d₄ of the device in FIG. 1A. FIG. 4H is a device layout formed by a cell in FIG. 4G.

This embodiment provides a cell layout as shown in FIG. 4I and a corresponding device layout as shown in FIG. 4J, the length of the source region maintains the original size design, and the punching of the source region can be increased to meet the high-current requirement. Similarly, this embodiment also has the advantages of improving the safety operation region and meeting the vehicle-mounted requirement.

### Embodiment 8

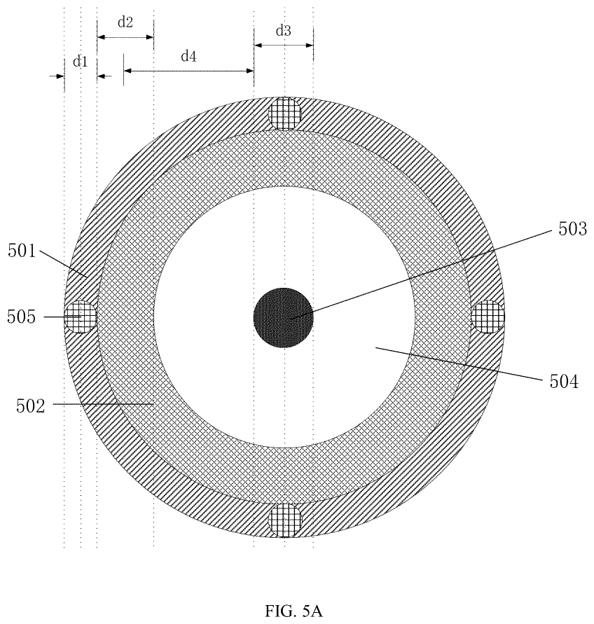

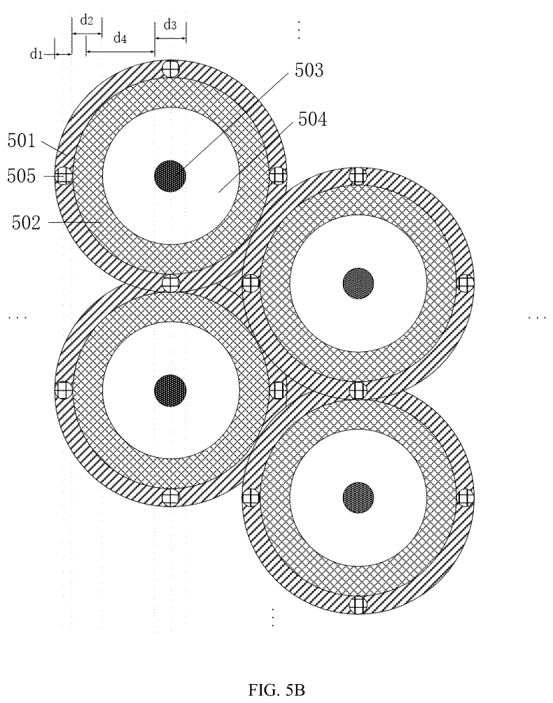

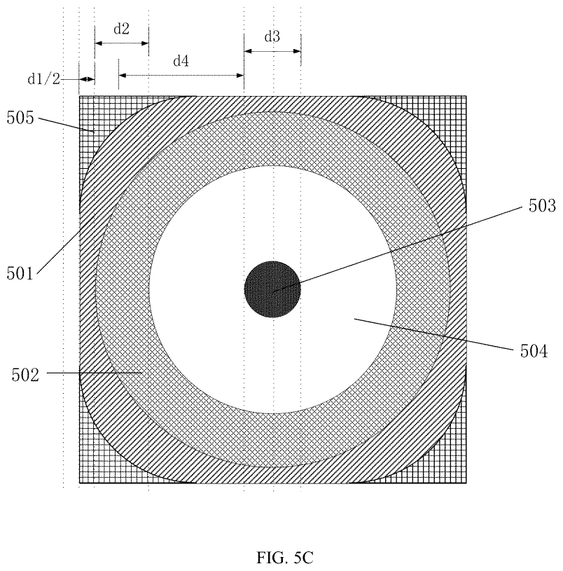

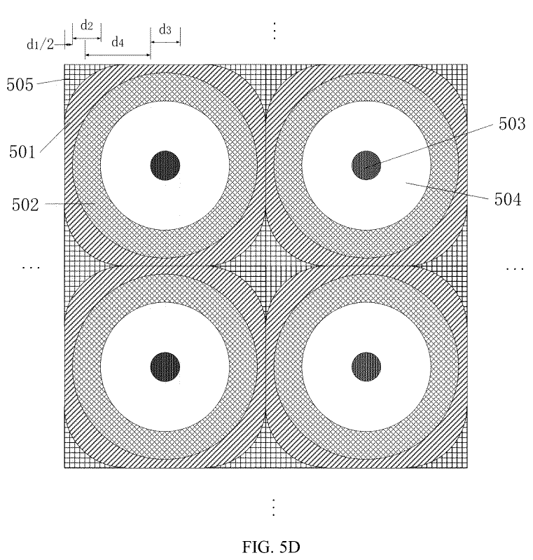

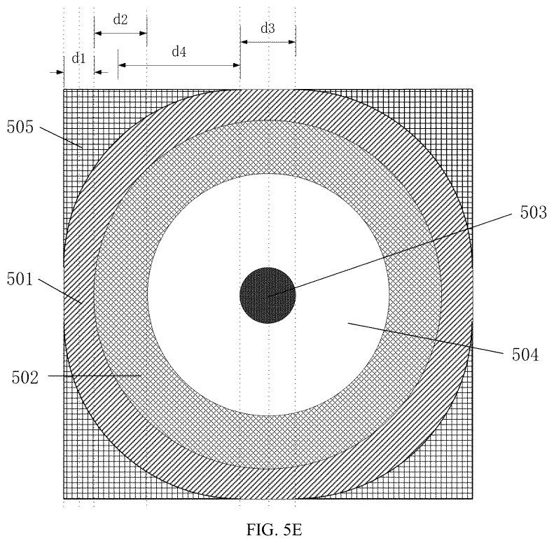

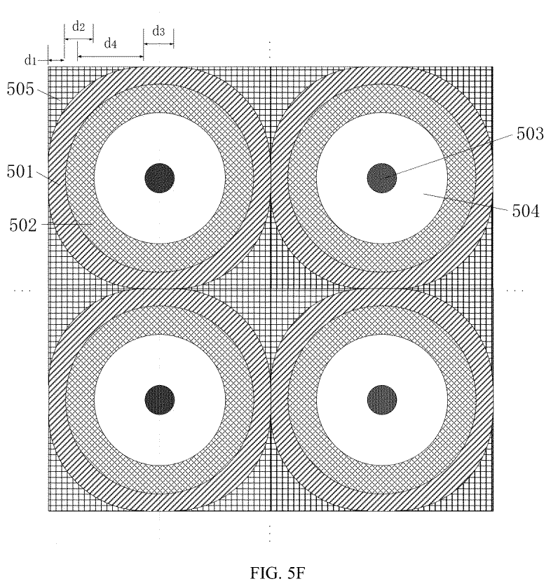

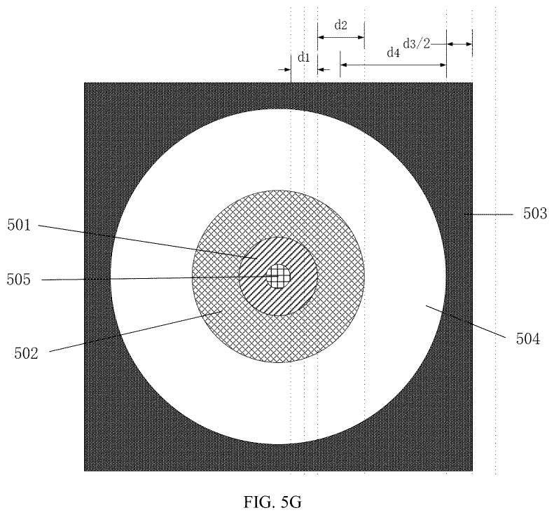

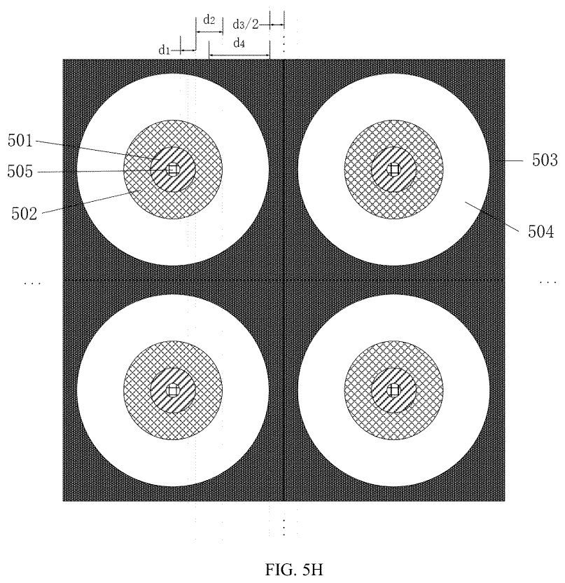

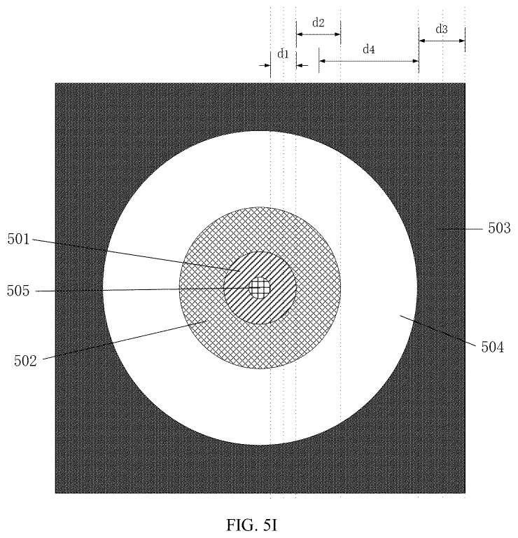

For Embodiment 8, as shown in FIG. 5A which is a drain electrode center circular cell layout of a lateral power semiconductor device with high integrity, this embodiment is different from Embodiment 1 in that: the drain electrode center cell layout is circular.

501 is a source region, 502 is a gate electrode, 503 is a drain region, 504 is a drift region, and 505 is a body region. A length d₁ of the source region, a length d₂ of the gate electrode, a length d₃ of the drain region and a length d₄ of the drift region are kept consistent with sizes d₁-d₄ of the device in FIG. 1A. FIG. 5B is a device layout formed by a cell in FIG. 5A

This embodiment has the following advantages: the circular design further avoids the curvature effect and improves the reliability of the device; and the body region is integrated at the edge, so that the area utilization ratio of the device and the integrity of the device are increased.

Similarly, this embodiment provides a cell layout as shown in FIG. 5C and a corresponding device layout as shown in FIG. 5D, the length of the source region maintains the original size design, and the punching of the source region can be increased to meet the high-current requirement.

### Embodiment 9

For Embodiment 9, as shown in FIG. 5E which is a drain electrode center circular cell layout of a lateral power semiconductor device with high integrity, this embodiment is different from Embodiment 8 in that: adjacent columns of cells are staggered longitudinally, and/or are staggered transversely, thereby increasing the integrity of the device and defining repeated units of the cells closely arranged longitudinally as a column.

501 is a source region, 502 is a gate electrode, 503 is a drain region, 504 is a drift region, and 505 is a body region. A length d₁ of the source region, a length d₂ of the gate electrode, a length d₃ of the drain region and a length d₄ of the drift region are kept consistent with sizes d₁-d₄ of the device in FIG. 1A. FIG. 5F is a device layout formed by a cell in FIG. 5E.

This embodiment has the following advantages: compared with Embodiment 8 in which an edge is set as a body region, the splitting mode when the cells are integrated is changed, and by the staggered design, the integrity of the device is increased and the waste of area is reduced, thereby improving the flow capability of the device and facilitating the high-current application.

### Embodiment 10

For Embodiment 10, as shown in FIG. 5G which is a source electrode center circular cell layout of a lateral power semiconductor device with high integrity, this embodiment is different from Embodiment 2 in that: the source electrode center cell layout is circular.

501 is a source region, 502 is a gate electrode, 503 is a drain region, 504 is a drift region, and 505 is a body region. A length d₁ of the source region, a length d₂ of the gate electrode, a length d₃ of the drain region and a length d₄ of the drift region are kept consistent with sizes d₁-d₄ of the device in FIG. 1A. FIG. 5H is a device layout formed by a cell in FIG. 5G.

This embodiment provides a cell layout as shown in FIG. 5I and a corresponding device layout as shown in FIG. 5J, the length of the source region maintains the original size design, and the punching of the source region can be increased to meet the high-current requirement. Similarly, this embodiment also has the advantages of improving the safety operation region and meeting the vehicle-mounted requirement.

### Embodiment 11

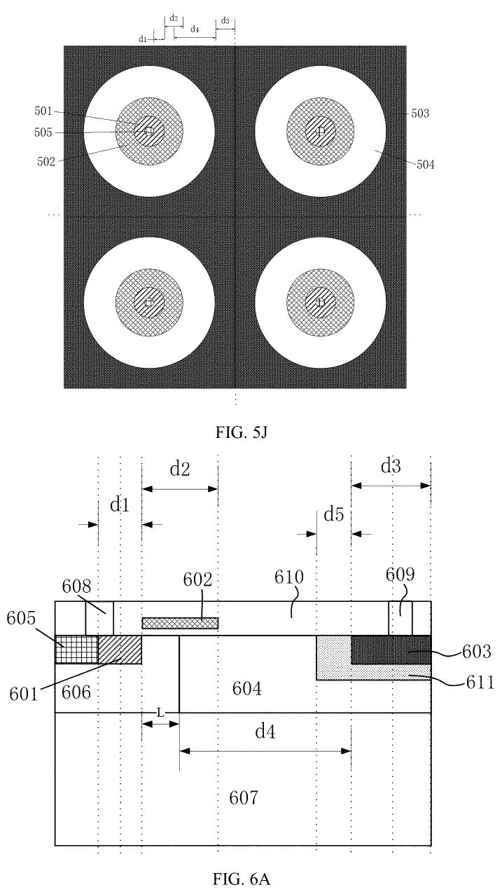

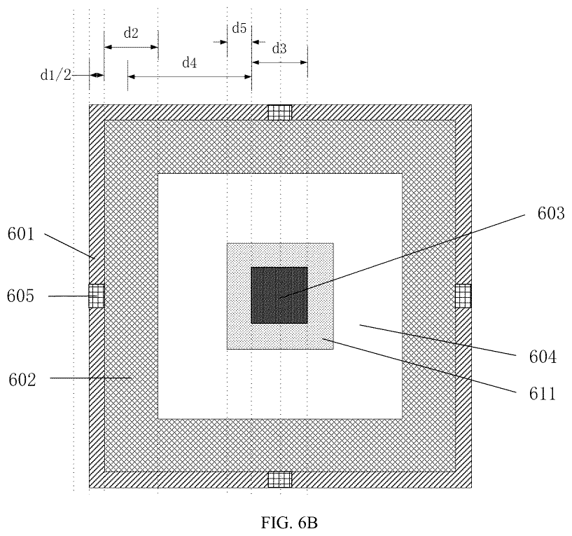

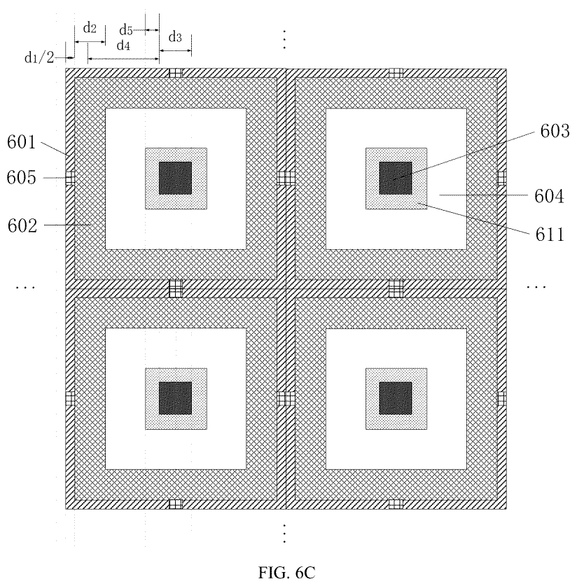

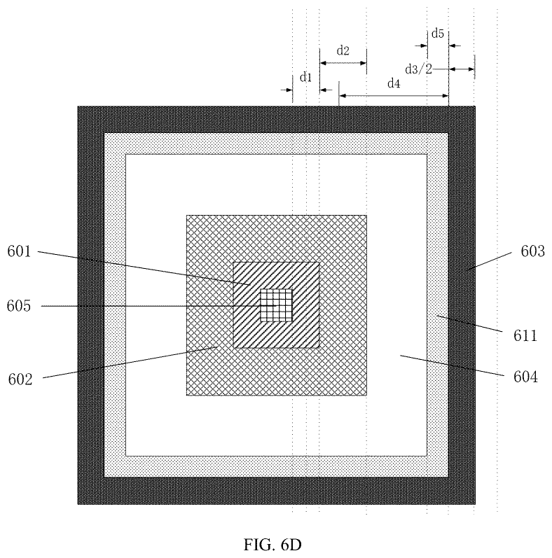

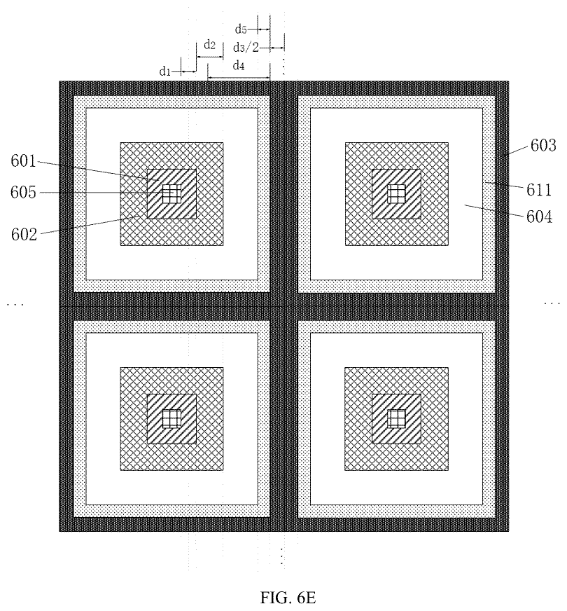

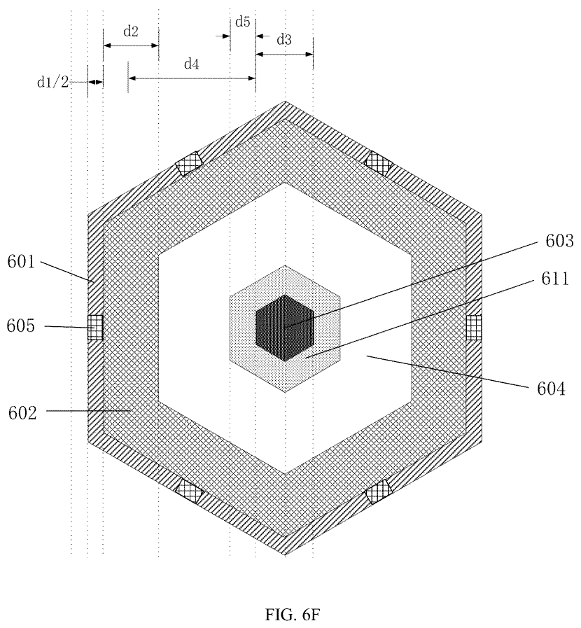

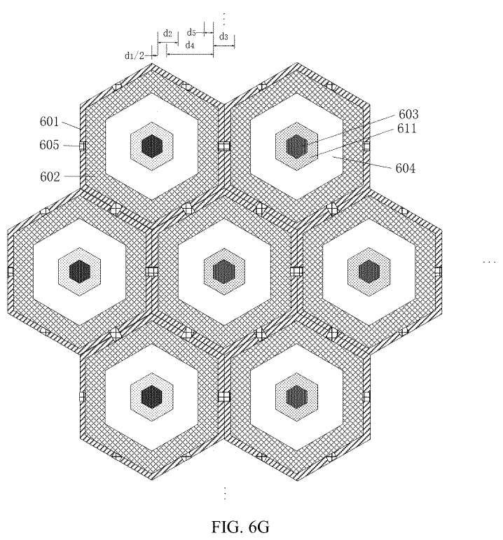

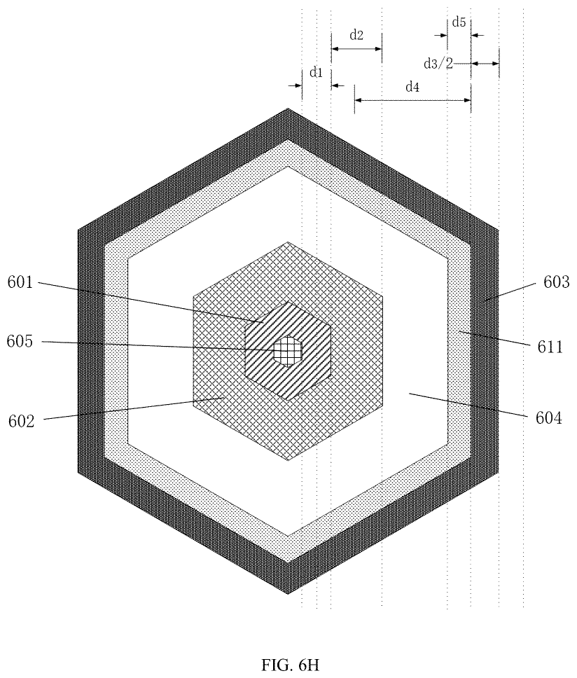

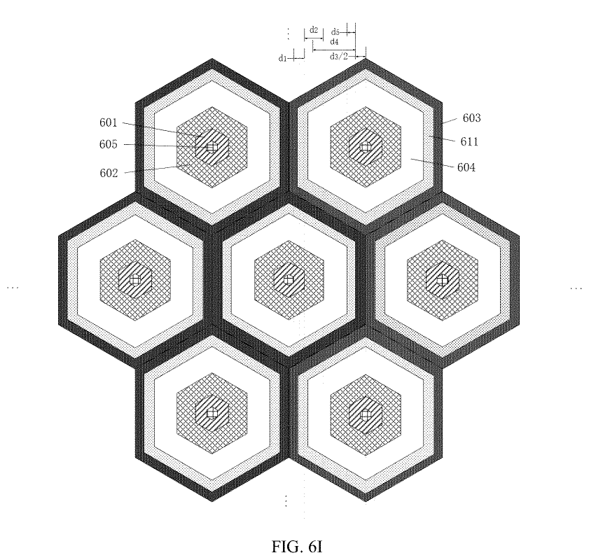

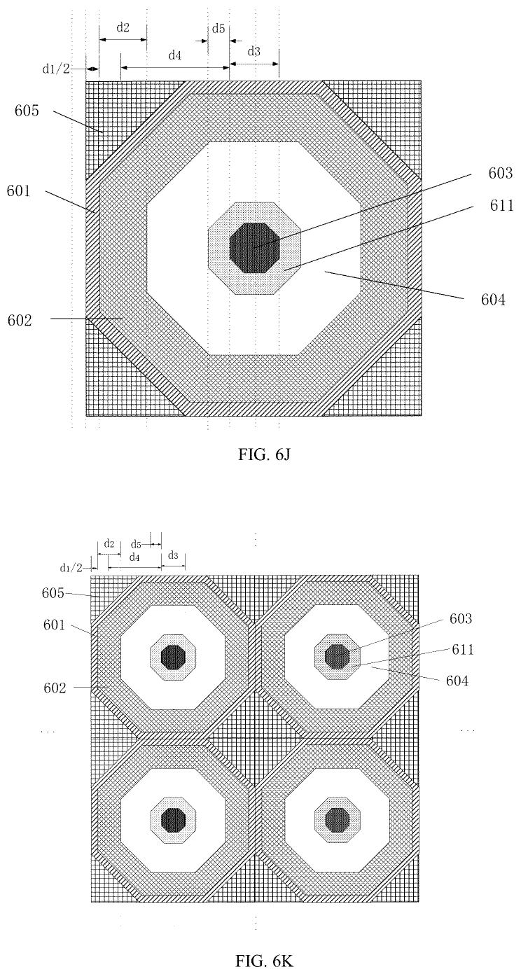

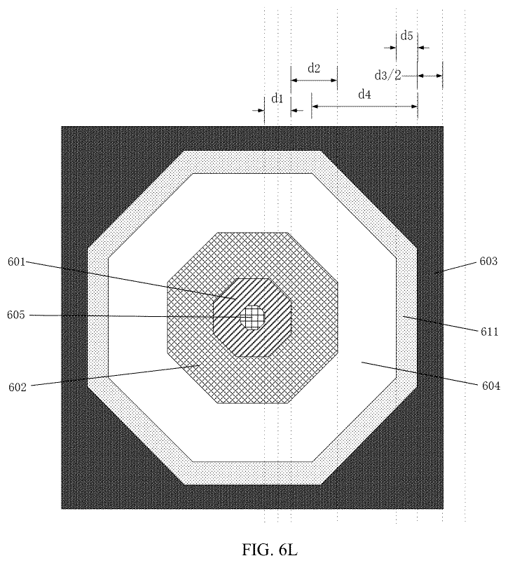

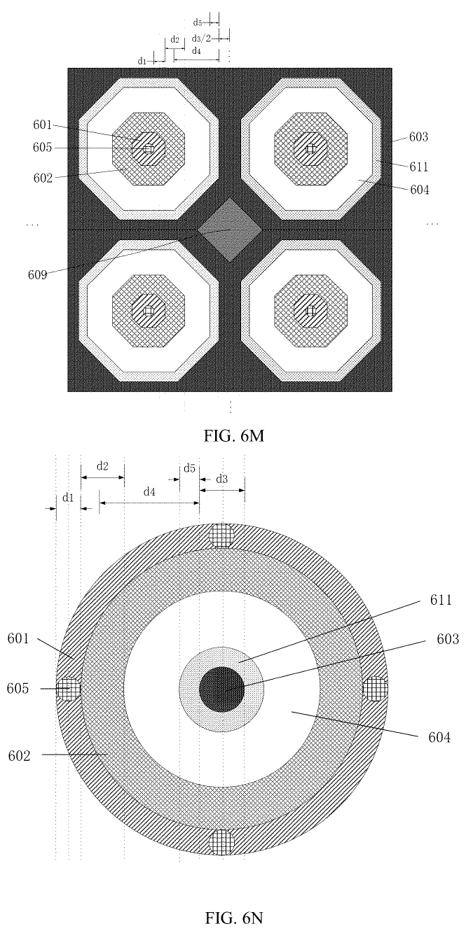

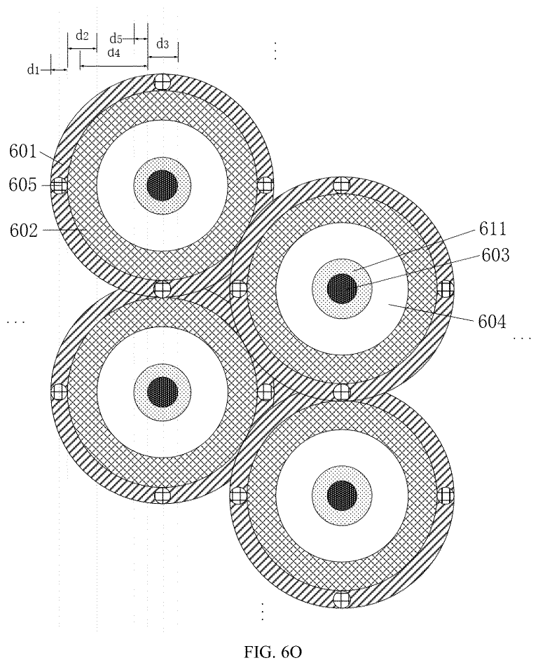

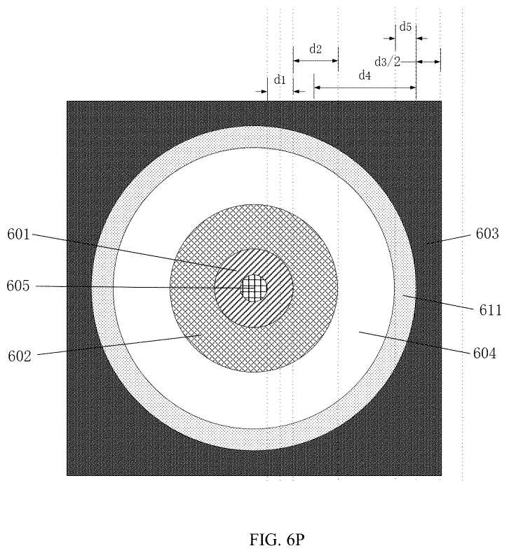

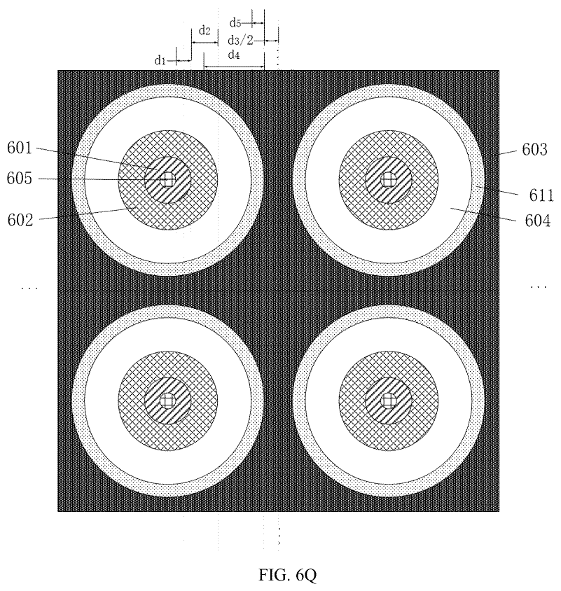

For Embodiment 11, as shown in FIG. 6A which is a lateral power semiconductor device structure using a single buffer layer.

In a first conduction type substrate 607, a second conduction type drift region 604 and a first conduction type first body region 606 are arranged on the substrate 607, a first conduction type second body region 605 and a second conduction type source region 601 are arranged in the first body region 606, a source electrode 608 is arranged above a second conduction type source region 601, a second conduction type drain region 603 and a second conduction type first buffer layer 611 are arranged in the drift region 604, a drain electrode 609 is arranged on the second conduction type drain region 603, and a left edge of a gate electrode 602 is tangent to a right edge of the source region 601. d1₁ is a length of the source region, d₂ is a length of the gate electrode, d₃ is a length of the drain region, d₄ is a length of the drift region, and d₅ is a length of the buffer layer beyond the drain region.

This embodiment can increase the doping concentration of the drift region, reduce the specific on-resistance of the device, optimize the depletion situation of the drift region in the on state of the device and reduce the surface current of the device, thereby improving the safety operation region of the device and the reliability of the device.

As shown in FIG. 6B, this embodiment provides a drain electrode center square cell layout of a lateral power semiconductor device with high integrity and using a single buffer layer, and a corresponding device layout is shown in FIG. 6C.

As shown in FIG. 6D, this embodiment provides a source electrode center square cell layout of a lateral power semiconductor device with high integrity and using a single buffer layer, and a corresponding device layout is shown in FIG. 6E.

As shown in FIG. 6F, this embodiment provides a drain electrode center hexagonal cell layout of a lateral power semiconductor device with high integrity and using a single buffer layer, and a corresponding device layout is shown in FIG. 6G.

As shown in FIG. 6H, this embodiment provides a source electrode center hexagonal cell layout of a lateral power semiconductor device with high integrity and using a single buffer layer, and a corresponding device layout is shown in FIG. 6I.

As shown in FIG. 6J, this embodiment provides a drain electrode center octagonal cell layout of a lateral power semiconductor device with high integrity and using a single buffer layer, and a corresponding device layout is shown in FIG. 6K.

As shown in FIG. 6L, this embodiment provides a source electrode center octagonal cell layout of a lateral power semiconductor device with high integrity and using a single buffer layer, and a corresponding device layout is shown in FIG. 6M.

As shown in FIG. 6N, this embodiment provides a drain electrode center circular cell layout of a lateral power semiconductor device with high integrity and using a single buffer layer, and a corresponding device layout is shown in FIG. 6O.

As shown in FIG. 6P, this embodiment provides a source electrode center circular cell layout of a lateral power semiconductor device with high integrity and using a single buffer layer, and a corresponding device layout is shown in FIG. 6Q.

Each method for designing the device layout corresponds to the advantages of the methods for designing the layout according to Embodiments 1-10.

### Embodiment 12

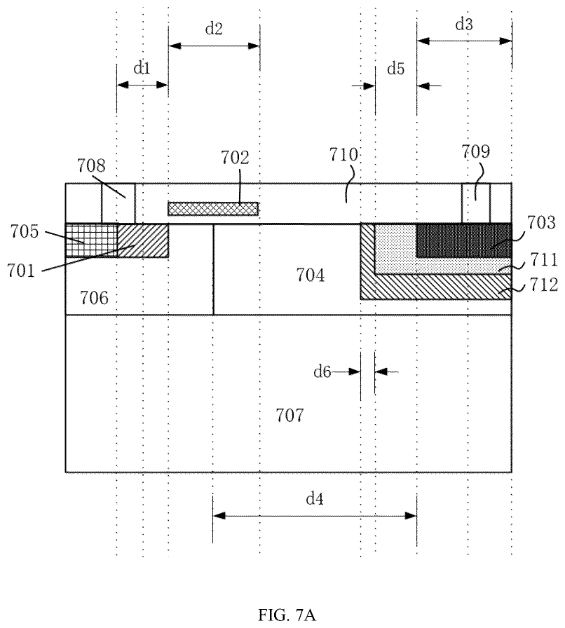

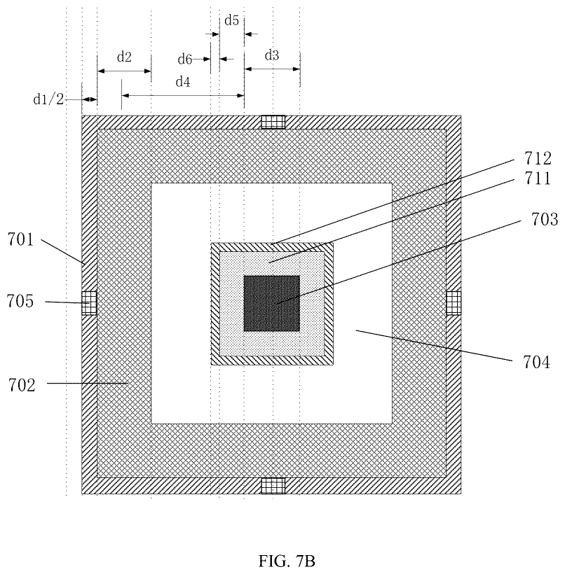

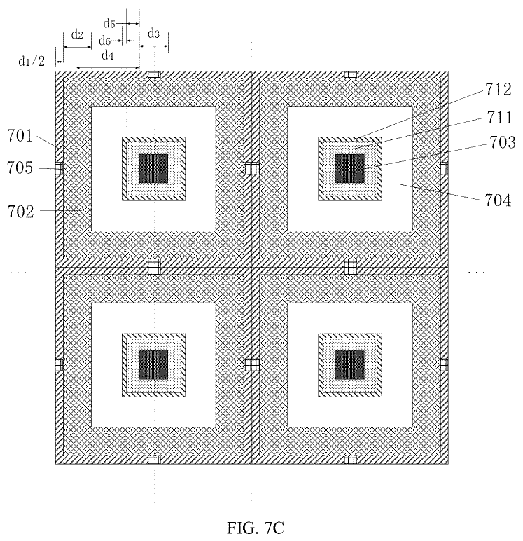

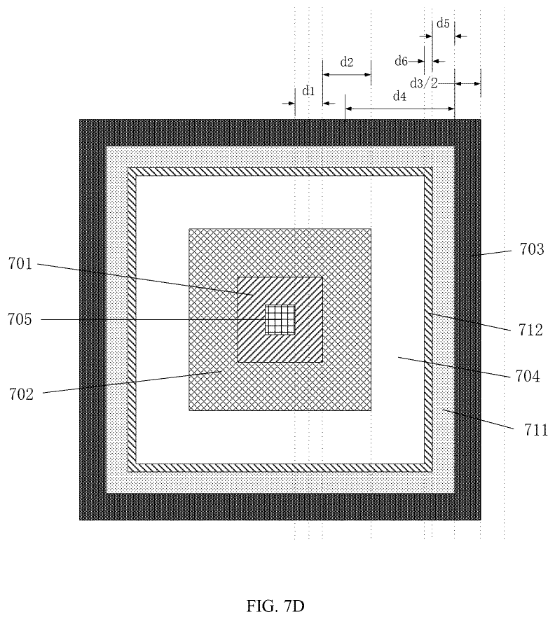

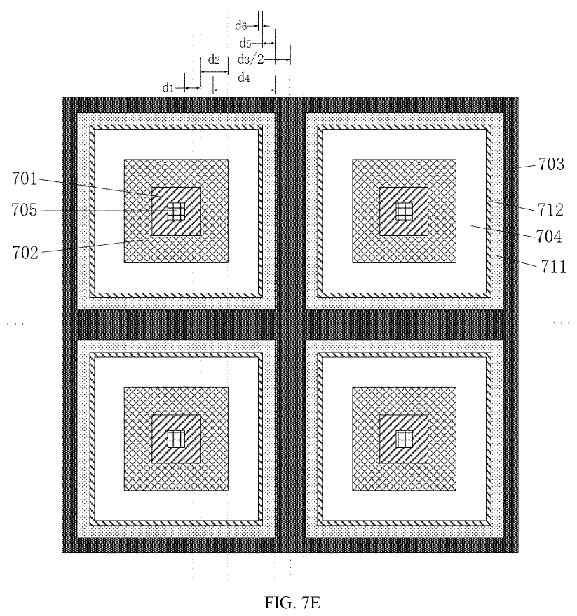

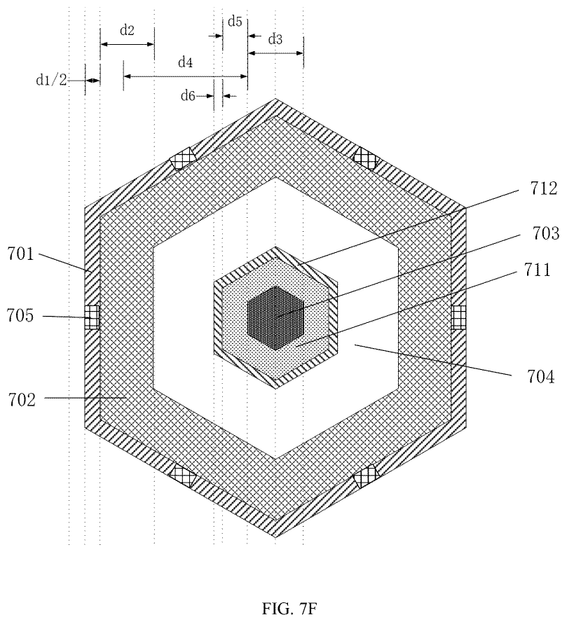

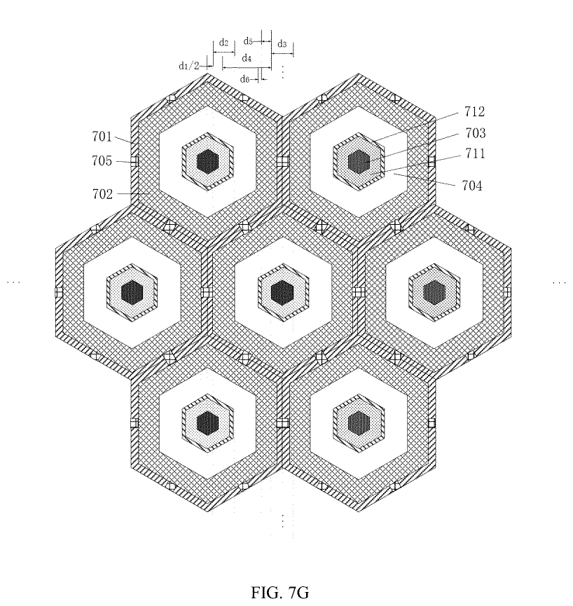

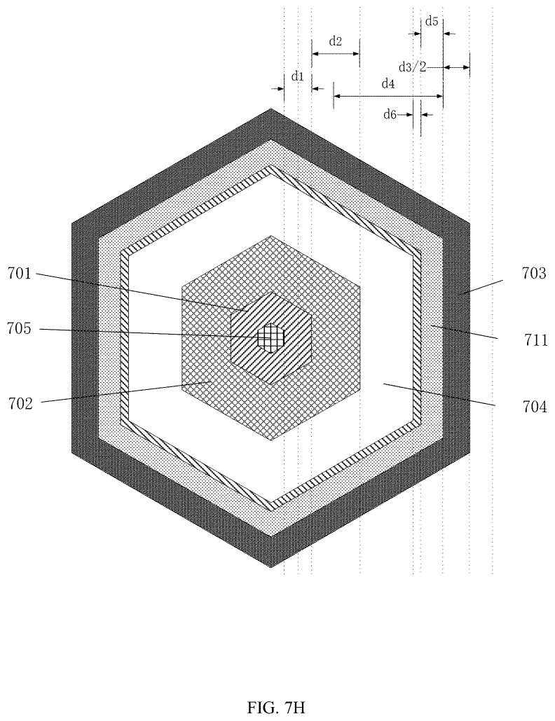

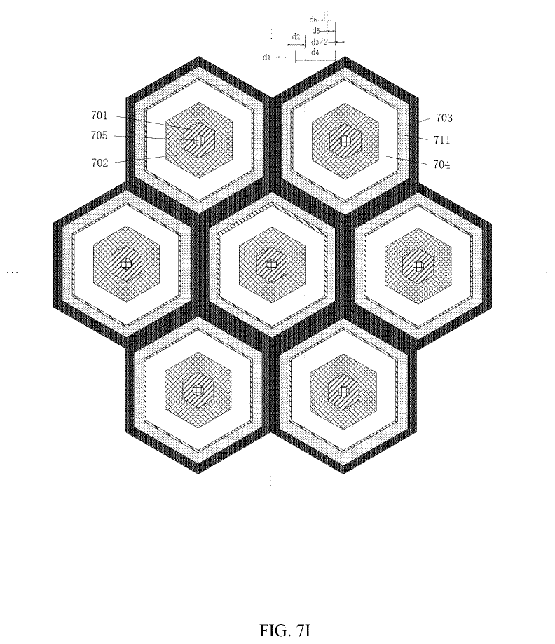

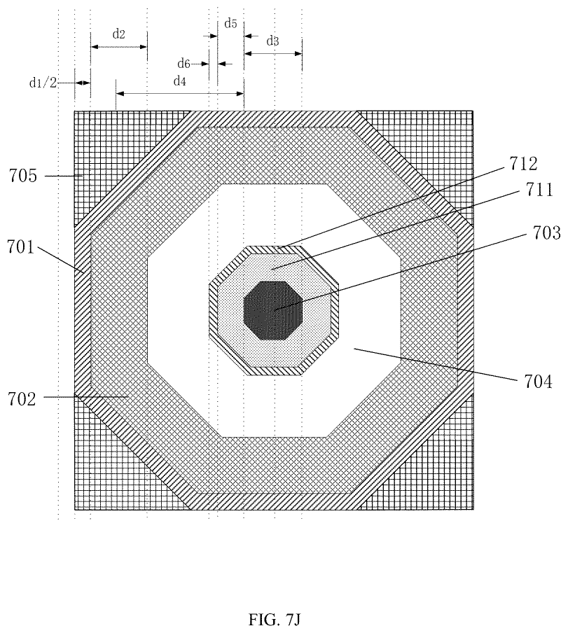

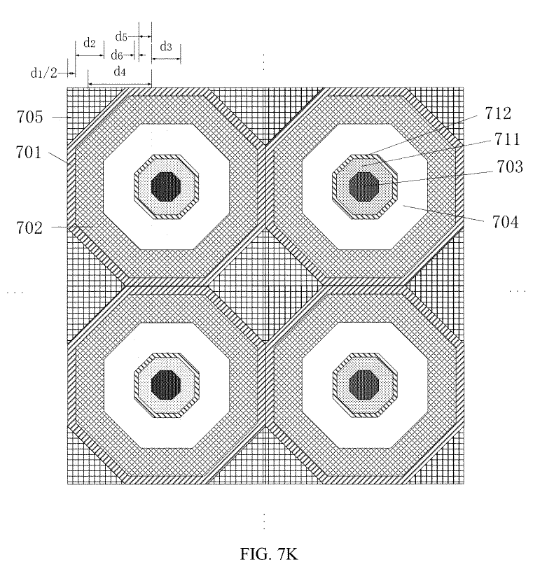

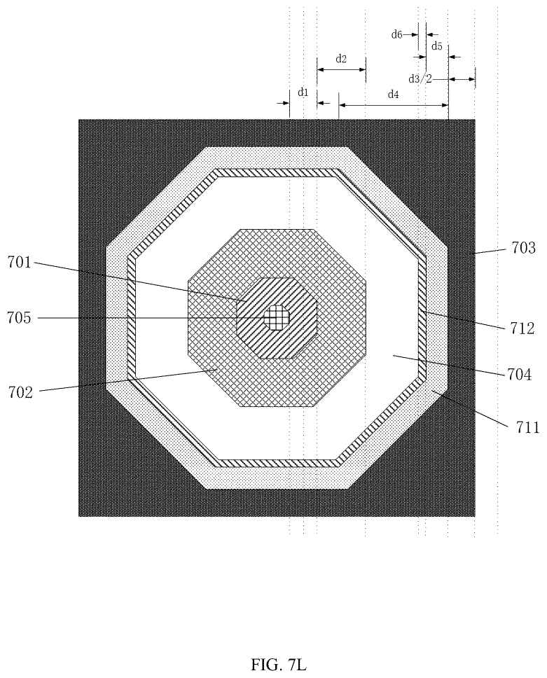

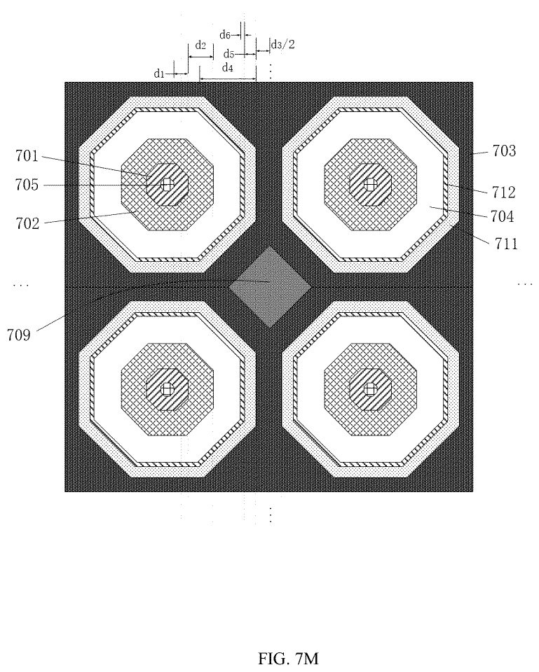

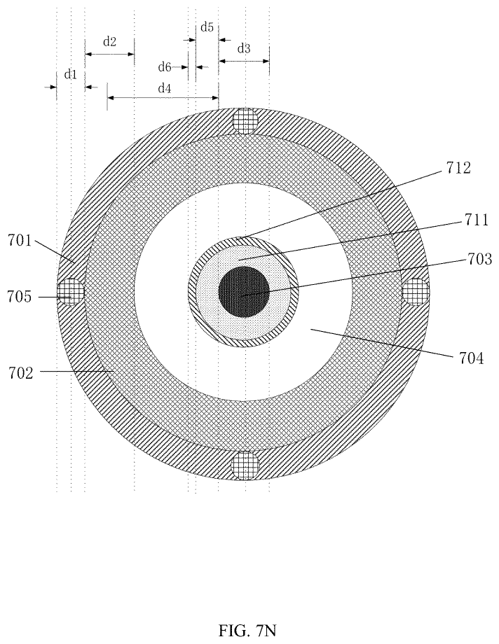

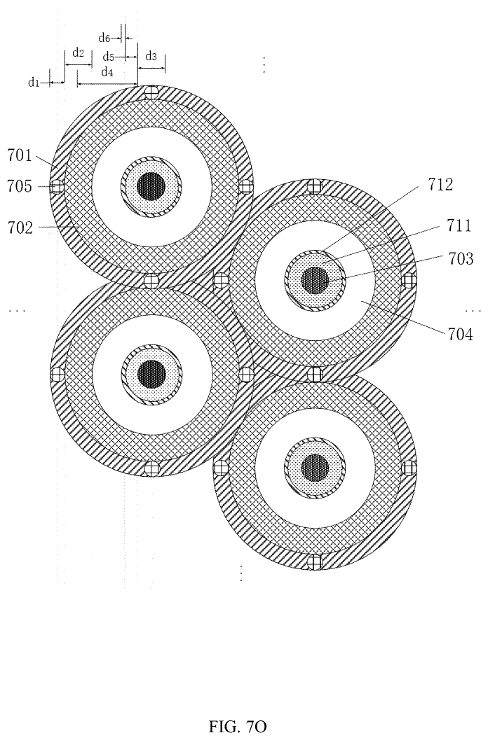

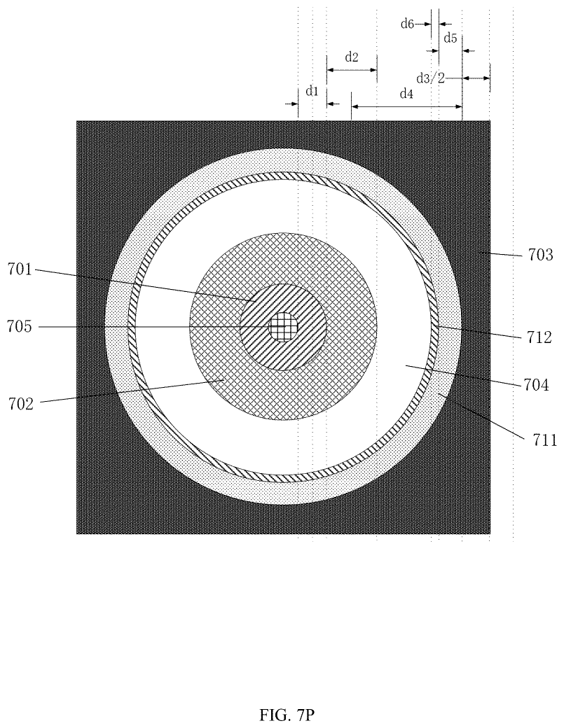

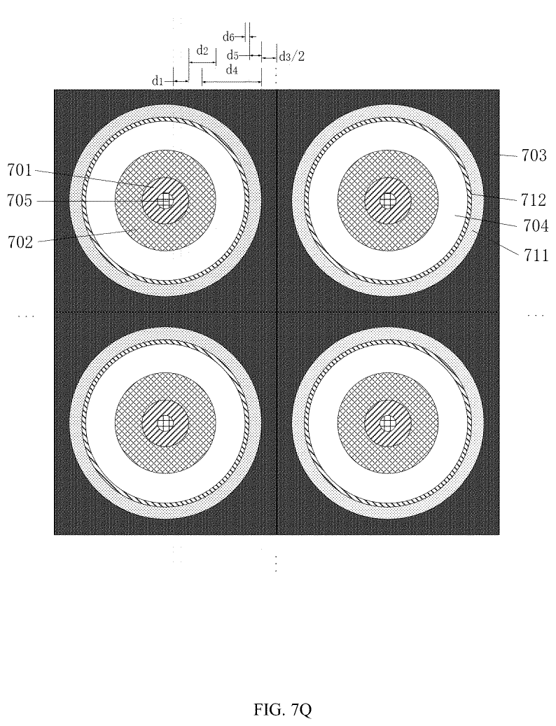

For Embodiment 12, as shown in FIG. 7A which is a lateral power semiconductor device structure using a stepped buffer layer,

this embodiment is different from Embodiment 11 in that: a second buffer layer 712 is arranged in the drift region 704; in a case that a doping type of the second buffer layer 712 is the same as a doping type of a first buffer layer 711, a thickness of the second buffer layer 712 is greater than or less than a thickness of the first buffer layer 711; and in a case that the doping type of the second buffer layer 712 is different from the doping type of the first buffer layer 711, the thickness of the second buffer layer 712 is less than the thickness of the first buffer layer 711, and a Double-RESURF structure is formed, so that the breakdown voltage of the device is improved.

A first conduction type substrate 707, where a second conduction type drift region 704 and a first conduction type first body region 706 are arranged on the first conduction type substrate 707, a first conduction type second body region 705 and a second conduction type source region 701 are arranged in the first body region 706, a source electrode 708 is arranged above a second conduction type source region 701, a second conduction type drain region 703, a second conduction type first buffer layer 711 and a second buffer layer 712 are arranged in the drift region 704, a drain electrode 709 is arranged on the second conduction type drain region 703, and a left edge of a gate electrode 702 is tangent to a right edge of the source region 701. d1₁ is a length of the source region, d₂ is a length of the gate electrode, d₃ is a length of the drain region, d₄ is a length of the drift region, and d₅ is a length of the buffer layer beyond the drain region. d6₆ is a length of the second buffer layer beyond the drain region.

This embodiment further adds a buffer layer based on Embodiment 11, thereby further reducing the specific on-resistance of the device, further improving the on-state breakdown voltage of the device and improving the reliability of the device.

As shown in FIG. 7B, this embodiment provides a drain electrode center square cell layout of a lateral power semiconductor device with high integrity and using a stepped buffer layer, and a corresponding device layout is shown in FIG. 7C.

As shown in FIG. 7D, this embodiment provides a source electrode center square cell layout of a lateral power semiconductor device with high integrity and using a stepped buffer layer, and a corresponding device layout is shown in FIG. 7E.

As shown in FIG. 7F, this embodiment provides a drain electrode center hexagonal cell layout of a lateral power semiconductor device with high integrity and using a stepped buffer layer, and a corresponding device layout is shown in FIG. 7G.

As shown in FIG. 7H, this embodiment provides a source electrode center hexagonal cell layout of a lateral power semiconductor device with high integrity and using a stepped buffer layer, and a corresponding device layout is shown in FIG. 7I.

As shown in FIG. 7J, this embodiment provides a drain electrode center octagonal cell layout of a lateral power semiconductor device with high integrity and using a stepped buffer layer, and a corresponding device layout is shown in FIG. 7K.

As shown in FIG. 7L, this embodiment provides a source electrode center octagonal cell layout of a lateral power semiconductor device with high integrity and using a stepped buffer layer, and a corresponding device layout is shown in FIG. 7M.

As shown in FIG. 7N, this embodiment provides a drain electrode center octagonal cell layout of a lateral power semiconductor device with high integrity and using a stepped buffer layer, and a corresponding device layout is shown in FIG. 70.

As shown in FIG. 7P, this embodiment provides a source electrode center octagonal cell layout of a lateral power semiconductor device with high integrity and using a stepped buffer layer, and a corresponding device layout is shown in FIG. 7Q.

Each method for designing the device layout corresponds to the advantages of the methods for designing the layout according to Embodiments 1-10.

In particular, a thickness of the second buffer layer 712 provided by this embodiment may be less than that of the first buffer layer 711, and may be flexibly adjusted according to the parameter requirement during the specific device design.

In particular, according to this embodiment, the buffer layer may be added to form more “stepped” doping, thereby further optimizing the characteristic of the device. Similarly, the doping thickness may be adjusted according to the parameter requirement during the device design.

In particular, in a case that the process permits, the thickness of the second conduction type second buffer layer 712 in this embodiment may be designed to be less than that of the first conduction type Double-RESURF region of the first buffer layer 711. Only using the Double-RESURF structure may lead to the increased on-resistance of the device, but has the effect of increasing the breakdown voltage of the device. By combining the Double-RESURF structure with the buffer layer, the static characteristic of the device can be further improved, and the static optimal value of the device can be increased.

In particular, according to this embodiment, in addition to that the buffer layer structure can be applied to quadrangular, hexagonal, octagonal and circular cells, the buffer layer structure for improving the characteristic of the device provided by the present invention is also suitable for triangular or other-shaped cells.

### Embodiment 13

For Embodiment 13, a lateral power semiconductor device structure with a terminal structure is provided, using the high-current lateral power semiconductor device layout structure of the above embodiment,

a first conduction type substrate 807, where a second conduction type buried layer 821 is arranged on the substrate 807, the buried layer 821 is connected to a second conduction type first connection region 819, a second conduction type isolating structure potential second connection region 816 is arranged in the first connection region 819, a second isolating structure electrode 812 is arranged on the second connection region 816, a first conduction type substrate potential connection region 817 is arranged in the substrate 807, a substrate electrode 813 is arranged on a substrate potential 817, a first conduction type well 820 is arranged on the buried layer 821, a first conduction type isolating structure potential first connection region 818 and a second connection region 815 in the first connection region 818 are arranged in the well 820, a first isolating structure electrode 811 is arranged on the second connection region 815 in the well, a drift region 804 and a first conduction type first body region 806 are arranged in the well, a first conduction type second body region 805 and a second conduction type resource region 801 are arranged in the first body region 806, a source electrode 808 is arranged on the source region 801, a second conduction type drain region 803 is arranged in the drift region 804, a drain electrode 809 is arranged on the second conduction type drain region 803, a left edge of the gate electrode 802 is tangent to a right edge of the source region 801, a field oxidation layer 810 covers a surface of the whole device, a right edge of the SAB structure 814 is tangent to a left edge of the drain region, a silicon local oxidation structure 822 is located between the electrodes, and a first conduction type first isolating structure electrode 811 is connected between the drain region 803 and the second isolating structure electrode 812.

d₁ is a length of the source region, d₂ is a length of the gate electrode, d₃ is a length of the drain region, d₄ is a length of the drift region, d₇ is a distance between the drain region and a first isolating region, d₈ is a width of the first isolating region, do is a distance between the first isolating region and a second isolating region, d₁₀ is a width of the second isolating region, d₁₁ is a distance between the second isolating region and the substrate potential connection region, and d₁₂ is a width of the substrate potential connection region.

In this embodiment, the first isolating structure 811 connected to a P-type epitaxy is arranged between the drain region 803 and the second isolating structure 812, so that different voltage biases may be applied to a drain terminal and the second isolating structure; furthermore, a drain terminal bias may be less than a substrate bias, thereby meeting the requirements of the device under different working states. In particular, a traditional right-angled terminal structure or a terminal structure with an optimized curvature effect is used, and the terminal structure with the optimized curvature effect is a terminal structure subjected to hexagonal, octagonal and circular processing at a corner.

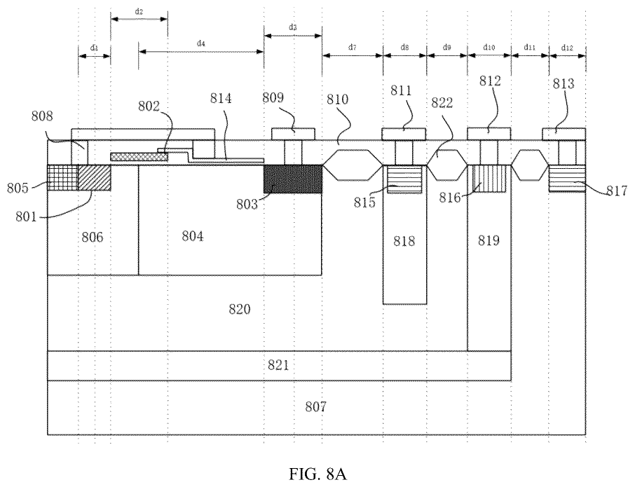

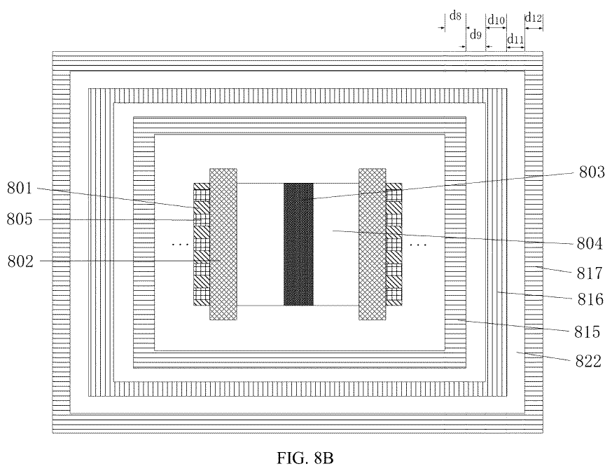

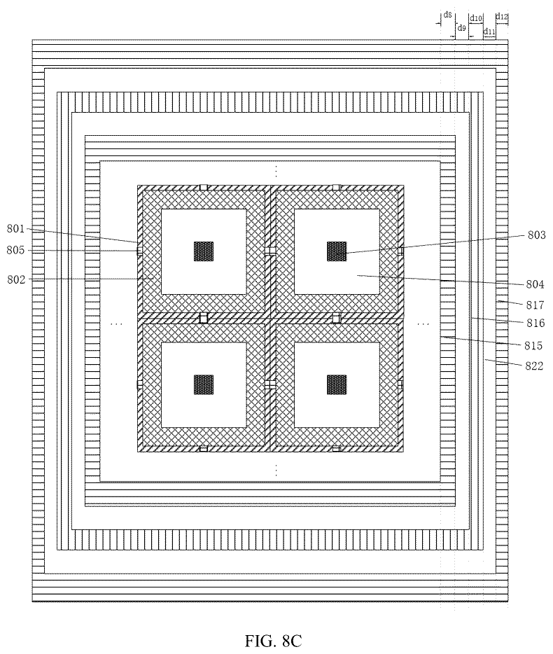

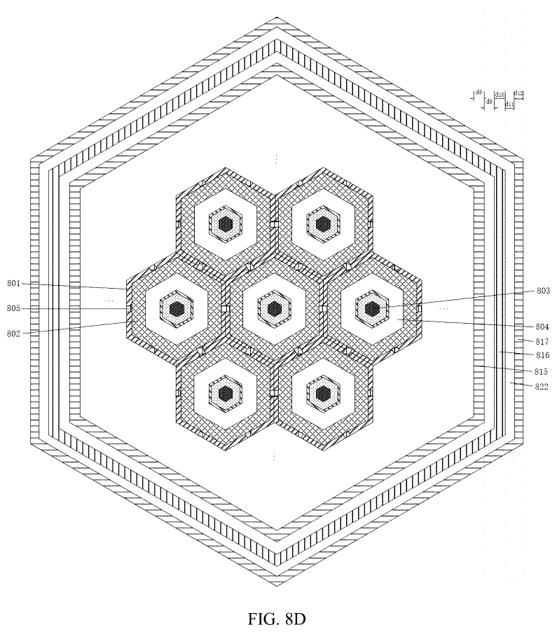

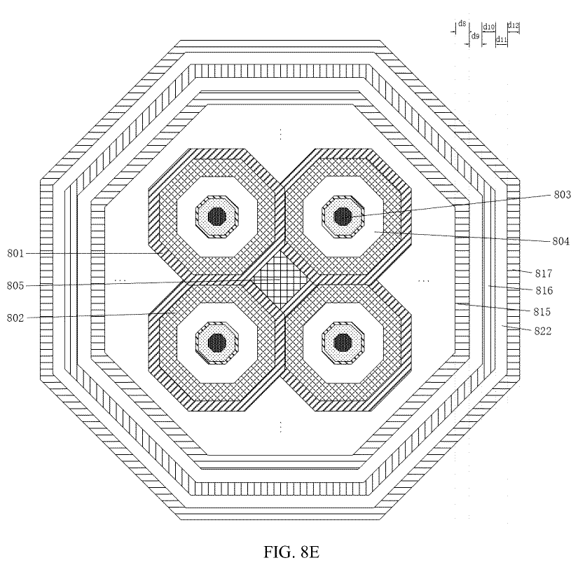

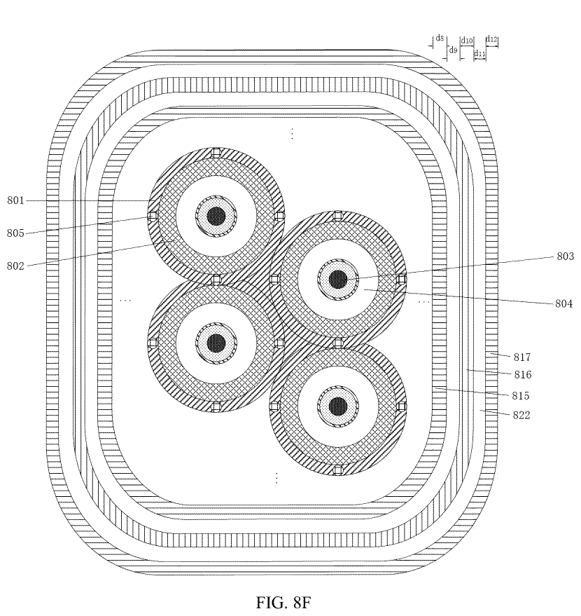

Corresponding to the cell and the isolating structure provided by this embodiment, FIG. 8B is a shared layout structure of a drain electrode center finger cell source electrode of a lateral power semiconductor device corresponding to FIG. 8A; FIG. 8C is a shared structure layout of a drain electrode center square cell source electrode of a lateral power semiconductor device corresponding to FIG. 8A; FIG. 8D is a shared structure layout of a drain electrode center hexagonal cell source electrode of a lateral power semiconductor device corresponding to FIG. 8A; FIG. 8E is a shared structure layout of a drain electrode center octagonal cell source electrode of a lateral power semiconductor device corresponding to FIG. 8A; and FIG. 8F is a shared structure layout of a drain electrode center circular cell source electrode of a lateral power semiconductor device corresponding to FIG. 8A.

In particular, the structures in the specification may be combined with each other, and parameters can be adjusted according to the actual process conditions to achieve the optimal characteristics of the device.

The above embodiments are only intended to exemplarily illustrate the principle and effect of the present invention, but not intended to limit the present invention. Any person skilled in the art can modify or change the above embodiments without departing from the spirit and scope of the present invention. Therefore, all equivalent modifications or changes made by those with ordinary knowledge in the art without departing the spirit and technical ideal disclosed by the present invention should still be covered within the claims of the present invention.

What is claimed is:

1. A lateral power semiconductor device layout structure, comprising:
a drain electrode central square cell layout comprising a source region, a gate electrode, a drain region, a drift region and a body region;
wherein the body region and the source region are jointly integrated in cells to reduce an area of a device and increase an integrity;
the drain region is located at a center of a layout, centers of the source region, the gate electrode and the drift region coincide with a center of the drain region, the drift region surrounds the drain region, the source region is tangent to an outer edge of the gate electrode, the body region is tangent to an inner edge and an outer edge of the source region, a length of the drift region is consistent with a length of the drift region of the device, a part of the gate electrode beyond an edge of the drift region serves as a field plate, and a static characteristic of the device is optimized;
the cells are closely arranged to form a corresponding device layout, and the cells of the device share the source region; and
a drain electrode central cell is of a polygonal structure with the number of sides greater than or equal to 3 or a circle, or the cells are integrated into a finger structure to increase a width-to-length ratio and improve a current capability of the device.

2. The lateral power semiconductor device layout structure according to claim 1, wherein a drain electrode central cell layout is triangular, quadrilateral, pentagonal, hexagonal, circular or octagonal.

3. The lateral power semiconductor device layout structure according to claim 1, wherein a length of the source region is half of a length dl of the source region in the device to increase the integrity, or is a length dl of the source region in the device to improve an overcurrent capability.

4. The lateral power semiconductor device layout structure according to claim 1, wherein the drain electrode central cell is octagonal, and a punching area at a shared source region of four adjacent cell centers is increased, thereby meeting high-current application, reducing the area of the device and increasing the integrity.

5. The lateral power semiconductor device layout structure according to claim 1, wherein the drain electrode central cell is circular, and adjacent columns of cells are staggered longitudinally and/or are staggered laterally, thereby increasing the integrity of the device and defining repeated units of the cells closely arranged longitudinally as a column.

6. A lateral power semiconductor device layout structure, comprising:
a source electrode central square cell layout comprising a source region, a gate electrode, a drain region, a drift region and a body region;
wherein the body region is located at a center of a layout, centers of the source region, the drain region, the gate electrode and the drift region coincide with a center of the body region, the source region is tangent to an outer edge of the body region, the gate electrode is tangent to an outer edge of the source region, the drift region is tangent to an inner edge of the drain region, a length of the drift region is consistent with a length of the drift region of a device, a part of the gate electrode beyond an edge of the drift region serves as a field plate, and a static characteristic of the device is optimized;
cells are closely arranged to form a corresponding device layout, and the cells of the device share the drain region;
a source electrode central cell is of a polygonal structure or a circle with the number of sides greater than or equal to 3, or the cells are integrated into an finger structure; and
the square cells are closely arranged to form a corresponding device layout.

7. The lateral power semiconductor device layout structure according to claim 6, wherein a source electrode central cell layout is triangular, quadrilateral, pentagonal, hexagonal, circular or octagonal.

8. The lateral power semiconductor device layout structure according to claim 6, wherein a length of the source region is half of a length d1 of the source region in the device to increase the integrity, or is a length d1 of the source region in the device to improve an overcurrent capability.

9. The lateral power semiconductor device layout structure according to claim 6, wherein the source electrode central cell is octagonal, and a punching area at a shared drain region of four adjacent cell centers is increased, thereby meeting high-current application, reducing the area of the device and increasing the integrity.

10. The lateral power semiconductor device layout structure according to claim 6, wherein the source electrode central cell is circular, and adjacent columns of cells are staggered longitudinally and/or are staggered laterally, thereby increasing the integrity of the device and defining repeated units of the cells closely arranged longitudinally as a column.

11. A lateral power semiconductor device structure using a buffer layer, using the high-current lateral power semiconductor device layout structure according to claim 1, further comprising:
a first conduction type substrate, where a second conduction type drift region and a first conduction type first body region are arranged on the substrate, a first conduction type second body region and a second conduction type source region are arranged in the first body region, a source electrode is arranged above the second conduction type source region, a second conduction type drain region and a second conduction type first buffer layer are arranged in the drift region, a drain electrode is arranged on the second conduction type drain region, and a left edge of a gate electrode is tangent to a right edge of the source region.

12. The lateral power semiconductor device structure using the buffer layer according to claim 11, wherein a second buffer layer is arranged in the drift region; in a case that a doping type of the second buffer layer is the same as a doping type of the first buffer layer, a thickness of the second buffer layer is greater than or less than a thickness of the first buffer layer; and in a case that the doping type of the second buffer layer is different from the doping type of the first buffer layer, the thickness of the second buffer layer is less than the thickness of the first buffer layer, and a Double-RESURF structure is formed, so that a breakdown voltage of the device is improved.

13. The lateral power semiconductor device structure using the buffer layer according to claim 12, wherein at least three buffer layers are arranged in the drift region to further optimize a static characteristic of the device;
or the static characteristic of the device is further optimized by combining the Double-RESURF structure and the buffer layer, thereby increasing a static optimal value of the device.

14. A lateral power semiconductor device structure with a terminal structure, using the high-current lateral power semiconductor device layout structure according to claim 1, further comprising:
a first conduction type substrate, wherein a second conduction type buried layer is arranged on the substrate, the buried layer is connected to a second conduction type first connection region, a second conduction type isolating structure potential second connection region is arranged in the first connection region, a second isolating structure electrode is arranged on the second connection region, a first conduction type substrate potential connection region is arranged in the substrate, a substrate electrode is arranged on a substrate potential, a first conduction type well is arranged on the buried layer, a first conduction type isolating structure potential first connection region and a second connection region in the first connection region are arranged in the well, a first isolating structure electrode is arranged on the second connection region in the well, a drift region and a first conduction type first body region are arranged in the well, a first conduction type second body region and a second conduction type source region are arranged in the first body region, a source electrode is arranged on the source region, a second conduction type drain region is arranged in the drift region, a drain electrode is arranged on the second conduction type drain region, a left edge of a gate electrode is tangent to a right edge of the source region, a field oxidation layer covers a surface of the whole device, a right edge of an SAB structure is tangent to a left edge of the drain region, a silicon local oxidation structure is located between the electrodes, and a first conduction type first isolating structure electrode is connected between the drain region and the second isolating structure electrode.

15. The lateral power semiconductor device structure with the terminal structure according to claim 14, wherein different voltage biases are applied to the drain region and the second isolating structure electrode, and a drain terminal bias is less than a substrate bias, thereby meeting requirements of the device under different working states.

16. The lateral power semiconductor device structure with the terminal structure according to claim 14, wherein a traditional right-angled terminal structure or a terminal structure with an optimized curvature effect is used, and the terminal structure with the optimized curvature effect comprises a terminal structure subjected to hexagonal, octagonal or circular processing at a corner.

17. The lateral power semiconductor device structure using the buffer layer according to claim 11, wherein in the lateral power semiconductor device layout structure, a drain electrode central cell layout is triangular, quadrilateral, pentagonal, hexagonal, circular or octagonal.

18. The lateral power semiconductor device structure using the buffer layer according to claim 11, wherein in the lateral power semiconductor device layout structure, a length of the source region is half of a length d1 of the source region in the device to increase the integrity, or is a length d1 of the source region in the device to improve an overcurrent capability.

19. The lateral power semiconductor device structure using the buffer layer according to claim 11, wherein in the lateral power semiconductor device layout structure, the drain electrode central cell is octagonal, and a punching area at a shared source region of four adjacent cell centers is increased, thereby meeting high-current application, reducing the area of the device and increasing the integrity.

20. The lateral power semiconductor device structure using the buffer layer according to claim 11, wherein in the lateral power semiconductor device layout structure, the drain electrode central cell is circular, and adjacent columns of cells are staggered longitudinally and/or are staggered laterally, thereby increasing the integrity of the device and defining repeated units of the cells closely arranged longitudinally as a column.
